(19) United States
(12) Patent Application Publication
(10) Pub. No.: US 2026/0074719 A1
(43) Pub. Date: Mar. 12, 2026

(54) RADIO-FREQUENCY CIRCUIT

(71) Applicant: Murata Manufacturing Co., Ltd., Nagaokakyo-shi (JP)

(72) Inventors: Hirotsugu MORI, Nagaokakyo-shi (JP); Atsushi HORITA, Nagaokakyo-shi (JP)

(73) Assignee: Murata Manufacturing Co., Ltd., Nagaokakyo-shi (JP)

(21) Appl. No.: 19/393,610

(22) Filed: Nov. 19, 2025

Related U.S. Application Data
(63) Continuation of application No. PCT/JP2024/008968, filed on Mar. 8, 2024.

(30) Foreign Application Priority Data
May 23, 2023 (JP) 2023-084291

(51) Int. Cl. H04B 1/00; H03H 9/64; H04B 1/40

(52) U.S. Cl. CPC H04B 1/006; H03H 9/64; H04B 1/40

(57) ABSTRACT

A radio-frequency circuit includes first and second filters and a first switch. The first filter has a pass band including a first broadcast band for 5G broadcast. The second filter has a pass band including a second broadcast band for 5G broadcast and a first communication band for cellular mobile communication. The first switch includes first, second, and third terminals. The first switch is configured to connect the first terminal to at least one of the second terminal and the third terminal. The second broadcast band and the first communication band at least partially overlap each other and are positioned at a high frequency side or a low frequency side of the first broadcast band. The first filter is connected to the second terminal. The second filter is connected to the third terminal.

### CROSS-REFERENCE TO RELATED APPLICATIONS

This is a continuation application of PCT International Application No. PCT/JP2024/008968 filed on Mar. 8, 2024, designating the United States of America, which is based on and claims priority of Japanese Patent Application No. 2023-084291 filed on May 23, 2023. The entire disclosures of the above-identified applications, including the specifications, drawings, and claims are incorporated herein by reference in their entirety.

### BACKGROUND

### 1. Field

The present disclosure relates to a radio-frequency circuit.

### 2. Description of the Related Art

It is desired that a multiband- and multimode-support radio-frequency circuit transmit and receive multiple radio-frequency signals with a small loss and a high isolation.

U.S. Patent Application Publication No. 2016/0127015 discloses a receive module (transfer circuit) configured in which multiple filters having different pass bands are connected to an antenna via a multiplexer (switch).

### SUMMARY

3GPP (registered trademark) (3rd Generation Partnership Project) is developing a 5G (5th generation) broadcast system for receiving a television broadcast signal with a low-gain antenna of a mobile terminal using a cellular 5G line, instead of using a television antenna employed in digital terrestrial communication. This 5G broadcast system, however, may encounter a problem of interference between a 5G broadcast reception signal and a cellular communication band signal located close to a 5G broadcast band.

The present disclosure is directed to a radio-frequency circuit that is able to receive a 5G broadcast signal while reducing interference with a cellular communication band.

According to an embodiment, there is provided a radio-frequency circuit including first and second filters and a first switch. The first filter has a pass band including a first broadcast band for 5G broadcast. The second filter has a pass band including a second broadcast band for 5G broadcast and a first communication band for cellular mobile communication. The first switch includes first, second, and third terminals. The first switch switches between connection of the first terminal to the second terminal and disconnection of the first terminal from the second terminal and also switches between connection of the first terminal to the third terminal and disconnection of the first terminal from the third terminal. The second broadcast band and the first communication band at least partially overlap each other and are positioned at a high frequency side or a low frequency side of the first broadcast band. The first terminal is connected to an antenna connection terminal. The second terminal is connected to the first filter. The third terminal is connected to the second filter.

According to an embodiment, a radio-frequency circuit that is able to receive a 5G broadcast signal while reducing interference with a cellular communication band may be provided.

### BRIEF DESCRIPTION OF THE DRAWINGS

FIG. 1 is a circuit diagram of a radio-frequency circuit and a communication device according to an embodiment;

FIG. 2 is a diagram illustrating an example of the relationships between frequency bands to be applied to the radio-frequency circuit of the embodiment and an example of the bandpass characteristics of filters of the radio-frequency circuit;

FIG. 3 is a circuit diagram of a radio-frequency circuit and a communication device according to a first modified example of the embodiment;

FIG. 4 is a diagram illustrating an example of the relationships between frequency bands to be applied to the radio-frequency circuit of the first modified example and an example of the bandpass characteristics of filters of the radio-frequency circuit;

FIG. 5 is a circuit diagram of a radio-frequency circuit and a communication device according to a second modified example of the embodiment;

FIG. 6 is a circuit diagram of a radio-frequency circuit according to a third modified example of the embodiment;

FIG. 7 is a circuit diagram of a radio-frequency circuit and a communication device according to a fourth modified example of the embodiment;

FIG. 8 is a diagram illustrating an example of the relationships between frequency bands to be applied to the radio-frequency circuit of the fourth modified example and an example of the bandpass characteristics of filters of the radio-frequency circuit;

FIG. 9A is a circuit state diagram illustrating a first signal transmission state of a radio-frequency circuit and a communication device according to a fifth modified example of the embodiment;

FIG. 9B is a circuit state diagram illustrating a second signal transmission state of the radio-frequency circuit and the communication device according to the fifth modified example of the embodiment; and

FIG. 10 is a circuit diagram of a radio-frequency circuit and a communication device according to a sixth modified example of the embodiment.

### DESCRIPTION OF THE EMBODIMENTS

Embodiments of the disclosure will be described below in detail with reference to the accompanying drawings. The embodiments described below illustrate general or specific examples. Numerical values, shapes, materials, components, and positions and connection states of the components explained in the following embodiments are only examples and are not intended to limit the disclosure.

The drawings are only schematically shown and are not necessarily precisely illustrated. For the sake of representation, the drawings may be illustrated in an exaggerated manner or with omissions or the ratios of components in the drawings may be adjusted. The shapes, positional relationships, and ratios of components in the drawings may be different from those of the actual components. In the drawings, components having substantially the same configuration are designated by like reference numeral, and it may be possible that an explanation of such components be not repeated or be merely simplified.

In the disclosure, “A is connected to B” includes, not only the meaning that A is directly connected to B using a connection terminal and/or a wiring conductor, but also the meaning that A is electrically connected to B via another circuit element. “Being connected between A and B” means that “being connected to both A and B on a path which connects A and B”, i.e., that a component is on a signal path that extends from A to B.

In the disclosure, “transmit path” means a transmission line constituted by wiring for transferring a radio-frequency transmission signal, an electrode directly connected to the wiring, and a terminal directly connected to the wiring or the electrode, for example. In the disclosure, “receive path” means a transmission line constituted by wiring for transferring a radio-frequency reception signal, an electrode directly connected to the wiring, and a terminal directly connected to the wiring or the electrode, for example.

### Embodiment

### 1 Circuit Configurations of Radio-Frequency Circuit 1 and Communication Device 4

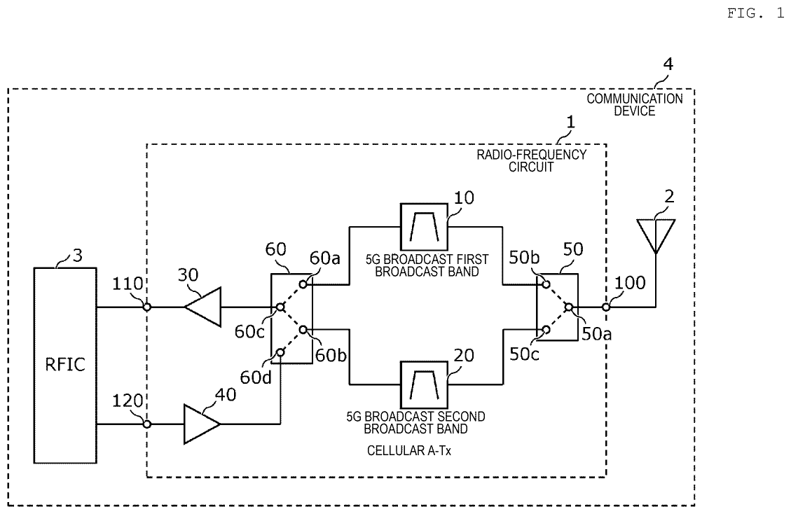

The circuit configurations of a radio-frequency circuit 1 and a communication device 4 according to an embodiment will be described below with reference to FIG. 1. FIG. 1 is a circuit diagram of the radio-frequency circuit 1 and the communication device 4 according to the embodiment.

### [1.1 Circuit Configuration of Communication Device 4]

The circuit configuration of the communication device 4 will first be explained. As illustrated in FIG. 1, the communication device 4 according to the embodiment includes the radio-frequency circuit 1, an antenna 2, and a radio-frequency (RF) signal processing circuit 3. Hereinafter, the radio-frequency (RF) signal processing circuit 3 will be called an RFIC (radio-frequency integrated circuit) 3.

The radio-frequency circuit 1 transfers a radio-frequency signal between the antenna 2 and the RFIC 3. The detailed circuit configuration of the radio-frequency circuit 1 will be discussed later.

The antenna 2 is connected to an antenna connection terminal 100 of the radio-frequency circuit 1. The antenna 2 transmits a radio-frequency signal output from the radio-frequency circuit 1 and also receives a radio-frequency signal from an external source and outputs it to the radio-frequency circuit 1.

The RFIC 3 is an example of a signal processing circuit that processes a radio-frequency signal. The RFIC 3 will be explained more specifically below. The RFIC 3 performs signal processing, such as down-conversion, on a radio-frequency reception signal received via a receive path of the radio-frequency circuit 1 and outputs the resulting reception signal to a baseband signal processing circuit (baseband integrated circuit (BBIC)), which is not shown. The RFIC 3 also performs signal processing, such as up-conversion, on a transmission signal received from the BBIC and outputs the resulting radio-frequency transmission signal to a transmit path of the radio-frequency circuit 1. The RFIC 3 includes a controller that controls components, such as switches and amplifiers, of the radio-frequency circuit 1. All or some of the functions of the RFIC 3 as the controller may be installed outside the RFIC 3, such as in the BBIC or the radio-frequency circuit 1. The controller sends control signals to the components to configure the radio-frequency circuit 1 into a desired operational mode, such as a 5G broadcast reception mode or a cellular communication mode.

The antenna 2 is not an essential component for the communication device 4 of the embodiment.

### [1.2 Circuit Configuration of Radio-Frequency Circuit 1]

The circuit configuration of the radio-frequency circuit 1 will now be described below. As illustrated in FIG. 1, the radio-frequency circuit 1 includes filters 10 and 20, switches 50 and 60, a low-noise amplifier 30, a power amplifier 40, an antenna connection terminal 100, a radio-frequency output terminal 110, and a radio-frequency input terminal 120.

The antenna connection terminal 100 is connected to the antenna 2 and a terminal 50a of the switch 50. The radio-frequency input terminal 120 is connected to the RFIC 3 and the power amplifier 40 and is used for receiving a radio-frequency transmission signal from the RFIC 3. The radio-frequency output terminal 110 is connected to the RFIC 3 and the low-noise amplifier 30 and is used for outputting a radio-frequency reception signal to the RFIC 3.

The filter 10 is an example of a first filter and has a pass band including a first broadcast band for 5G broadcast. One end of the filter 10 is connected to a terminal 50b (second terminal) of the switch 50 (first switch), and the other end of the filter 10 is connected to a terminal 60a (fourth terminal) of the switch 60 (second switch).

The filter 20 is an example of a second filter and has a pass band including a second broadcast band for 5G broadcast and band A (first communication band) for cellular mobile communication. One end of the filter 20 is connected to a terminal 50c (third terminal) of the switch 50 (first switch), and the other end of the filter 20 is connected to a terminal 60b (fifth terminal) of the switch 60 (second switch).

The switch 50 is an example of a first switch and includes a terminal 50a (first terminal), the terminal 50b (second terminal), and the terminal 50c (third terminal). The switch 50 switches between the connection of the terminal 50a to the terminal 50b and the disconnection of the terminal 50a from the terminal 50b and also switches between the connection of the terminal 50a to the terminal 50c and the disconnection of the terminal 50a from the terminal 50c. That is, the switch 50 switches between the connection of the antenna 2 to the filter 10 and the disconnection of the antenna 2 from the filter 10 and also switches between the connection of the antenna 2 to the filter 20 and the disconnection of the antenna 2 from the filter 20.

The switch 50 may mutually exclusively perform the connection of the terminal 50a to the terminal 50b and the connection of the terminal 50a to the terminal 50c. This enables the radio-frequency circuit 1 to selectively perform the following operations: (1) receiving a 5G broadcast signal of the first broadcast band; and (2) receiving a 5G broadcast signal of the second broadcast band and/or performing communication of a cellular network signal of band A.

The low-noise amplifier 30 is an example of a first low-noise amplifier. The input end of the low-noise amplifier 30 is connected to a terminal 60c (sixth terminal) of the switch 60, and the output end of the low-noise amplifier 30 is connected to the radio-frequency output terminal 110. The low-noise amplifier 30 amplifies a 5G broadcast radio-frequency reception signal (hereinafter simply called a 5G broadcast reception signal) input from the antenna connection terminal 100.

The power amplifier 40 is an example of a first power amplifier. The output end of the power amplifier 40 is connected to a terminal 60d (seventh terminal) of the switch 60, and the input end of the power amplifier 40 is connected to the radio-frequency input terminal 120. The power amplifier 40 amplifies a radio-frequency transmission signal (hereinafter simply called a transmission signal) of band A input from the radio-frequency input terminal 120.

The switch 60 is an example of a second switch and includes the terminal 60a (fourth terminal), terminal 60b (fifth terminal), terminal 60c (sixth terminal), and terminal 60d (seventh terminal). The switch 60 switches between the connection of the terminal 60c to the terminal 60a and the connection of the terminal 60c to the terminal 60b and also switches between the connection of the terminal 60b to the terminal 60c and the connection of the terminal 60b to the terminal 60d. That is, the switch 60 performs the following switching operations: (1) switching between the connection of the low-noise amplifier 30 to the filter 10 and the connection of the low-noise amplifier 30 to the filter 20; and (2) switching between the connection of the filter 20 to the low-noise amplifier 30 and the connection of the filter 20 to the power amplifier 40. This enables the radio-frequency circuit 1 to selectively execute the following operations: (1) amplifying a 5G broadcast reception signal of the first broadcast band; (2) amplifying a 5G broadcast reception signal of the second broadcast band; and (3) amplifying a cellular network signal of band A.

In the disclosure, a first communication band (uplink operating band or downlink operating band of band A), a second communication band (uplink operating band or downlink operating band of band A), a third communication band, and a fourth communication band each refer to a frequency band defined by a standardizing body (such as 3GPP (registered trademark) and IEEE (Institute of Electrical and Electronics Engineers)) for a communication system to be constructed using a radio access technology (RAT). As the communication system, a LTE (Long Term Evolution) system, a 5G (5th Generation)—NR (New Radio) system, and a WLAN (Wireless Local Area Network) system, for example, may be used. However, the communication system is not limited to these types of systems.

The first broadcast band, the second broadcast band, and a third broadcast band each refer to a frequency band, which is defined by a standardizing body, such as 3GPP (registered trademark), for receiving a 5G broadcast signal.

For each of the first broadcast band, second broadcast band, and third broadcast band, one of the following bands, for example, may be used: (1) 470 to 612 MHz, (2) 470 to 663 MHz, (3) 470 to 698 MHz, (4) 612 to 652 MHz, and (5) 663 to 702 MHZ.

The 470 to 698 MHz band in the above-described frequency range (3) is defined as band 108 (Standalone Downlink Only (SDO)) for 5G broadcast. The 612 to 652 MHZ band in the above-described frequency range (4) is defined as band 107 (SDO) for 5G broadcast.

### [1.3 Bandpass Characteristics of Filters 10 and 20]

An explanation will now be given of the frequency bands to be applied to the radio-frequency circuit 1 of the embodiment and the signal transmission characteristics required for the radio-frequency circuit 1.

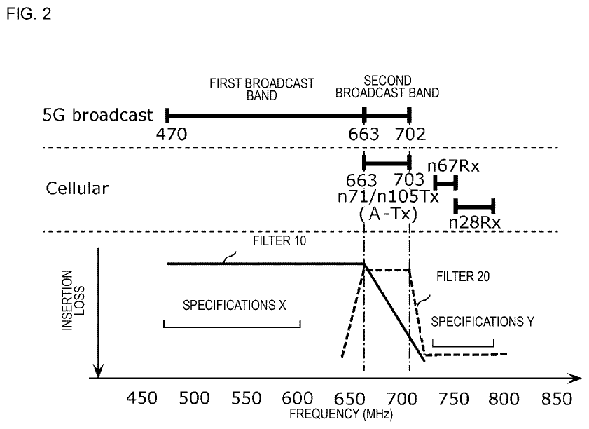

FIG. 2 is a diagram illustrating an example of the relationships between the frequency bands to be applied to the radio-frequency circuit 1 of the embodiment and an example of the bandpass characteristics of the filters 10 and 20. The upper section of FIG. 2 shows the frequency bands (first broadcast band and second broadcast band) used for receiving 5G broadcast signals and communication bands (n71/n105 uplink operating band, n67 downlink operating band, and n28 downlink operating band) allocated to cellular mobile communication.

5G broadcast is a system which is being developed by 3GPP (registered trademark) and is used for receiving a television broadcast signal. This system receives a television broadcast signal with a low-gain antenna of a mobile terminal using a cellular 5G line, instead of using a television antenna employed in digital terrestrial communication.

The frequency band of 5G broadcast signals varies by country or region and is planning to be divided into smaller band ranges, such as 470 to 542 MHz, 540 to 606 MHZ, and 602 to 702 MHz, for example, and be allocated. The channel bandwidth also varies by country or region and is planning to be set to 6 MHZ, 7 MHz, and 8 MHz, for example.

In contrast to 5G broadcast bands, 3GPP (registered trademark) has already allocated cellular communication bands for performing communication using a 4G/5G system and has put these bands to practical use.

As shown in FIG. 2, the frequency bands for receiving 5G broadcast signals by the radio-frequency circuit 1 and the communication device 4 of the embodiment are the first broadcast band and the second broadcast band. The second broadcast band is positioned at a higher frequency side than the first broadcast band. The second broadcast band at least partially overlaps the uplink operating band of band A for cellular mobile communication.

Specifications necessary for performing communication using band A are already set for 4G/5G cellular communication. It is thus necessary to satisfy specifications X for the low frequency side of band A and specifications Y for the high frequency side of band A. Specifications Y are those about the attenuation of a communication band (n67 downlink operating band, for example) located close to the high frequency side of the second broadcast band, for example.

If a 5G broadcast filter having a wide band including the first broadcast band and the second broadcast band is to be constituted by one filter, priority has to be given to the increase in the pass band width. Prioritizing the increase in the pass band width makes it difficult to sharpen the attenuation slope at the high frequency edge of the pass band. This may fail to satisfy specifications Y regarding the attenuation of a communication band close to the high frequency side of the second broadcast band. That is, the isolation between the 5G broadcast signals and the existing cellular communication bands located close to the first broadcast band and the second broadcast band becomes insufficient.

To address this issue, in the radio-frequency circuit 1 of the embodiment, the 5G broadcast filter is constituted by the filter 10 having the pass band including the first broadcast band and the filter 20 having the pass band including the second broadcast band. This can secure a large frequency interval between the pass band of the filter 10 and the existing cellular communication band located close to the high frequency side of the second broadcast band. The filter 10 can thus secure the attenuation of this existing cellular communication band, in other words, it can satisfy specifications Y. Regarding the filter 20 having the pass band including the second broadcast band, a filter having a pass band including the uplink operating band of band A, which is an existing cellular communication band, can be used as the filter 20. The filter 20 does not increase the pass band width and can thus secure a sufficient attenuation of the existing cellular communication band close to the second broadcast band. Hence, the radio-frequency circuit 1 is able to receive a 5G broadcast signal while reducing interference with a cellular communication band.

The filter 10 used for 5G broadcast does not need to increase the pass band width and can thus be reduced in size. The filter 20 can be used both for an existing cellular communication band and the second broadcast band for 5G broadcast. By reusing an existing cellular component, a small radio-frequency circuit 1 that can receive a 5G broadcast signal and also transmit band A for cellular communication may be realized.

In the radio-frequency circuit 1 of the embodiment, band A (first communication band) includes the uplink operating band. This enables the radio-frequency circuit 1 to selectively execute the following operations: (1) receiving a 5G broadcast signal of the first broadcast band; (2) receiving a 5G broadcast signal of the second broadcast band; and (3) transmitting a cellular network signal of band A.

The uplink operating band of band A is a frequency range used for uplink communication of band A. The downlink operating band of band A is a frequency range used for downlink communication of band A.

The filter 10 may be an LC filter including an inductor and a capacitor. There is a large frequency interval between the pass band of the filter 10 and that of the existing cellular communication band located close to the second broadcast band. The filter 10 can thus be formed by a low-loss and small-sized LC filter.

The filter 20 may be an acoustic wave filter including an acoustic wave resonator. The filter 20 having a small frequency interval with the existing cellular communication band close to the second broadcast band is formed by an acoustic wave filter, thereby making it possible to secure a large attenuation of this existing cellular communication band.

As illustrated in FIG. 2, in the radio-frequency circuit 1 of the embodiment, the first broadcast band is 470 to 663 MHz; the second broadcast band is 663 to 702 MHZ; and band A is one of the uplink operating band of band 71 or band 105 for 4G-LTE and the uplink operating band of band n71 or band n105 for 5G-NR.

In the embodiment, the second broadcast band is positioned at a higher frequency side than the first broadcast band. However, the second broadcast band may be positioned at a lower frequency side than the first broadcast band.

### 2 Circuit Configurations of Radio-Frequency Circuit 1A and Communication Device 4A of First Modified Example

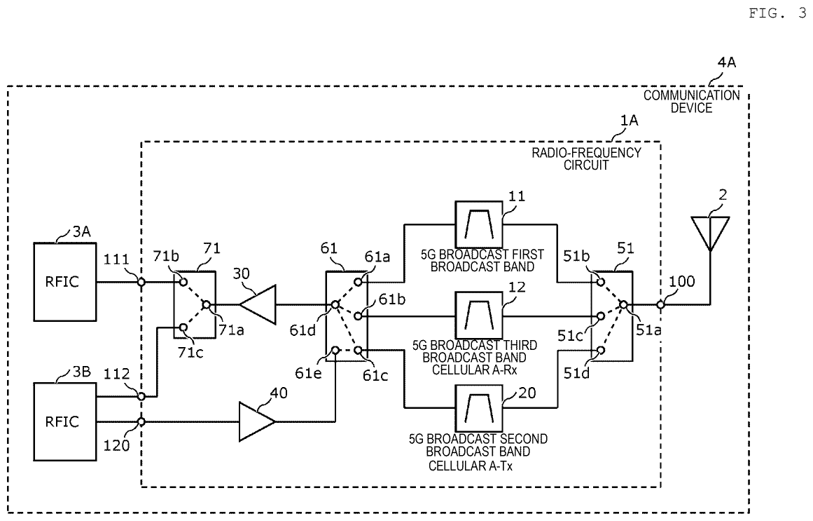

The circuit configurations of a radio-frequency circuit 1A and a communication device 4A according to a first modified example of the embodiment will be described below with reference to FIG. 3. FIG. 3 is a circuit diagram of the radio-frequency circuit 1A and the communication device 4A according to the first modified example of the embodiment.

### [2.1 Circuit Configuration of Communication Device 4A]

As illustrated in FIG. 3, the communication device 4A according to the first modified example includes the radio-frequency circuit 1A, an antenna 2, and RFICs 3A and 3B.

The radio-frequency circuit 1A transfers a radio-frequency signal between the antenna 2 and each of the RFICs 3A and 3B. The detailed circuit configuration of the radio-frequency circuit 1A will be discussed later.

The RFIC 3A is an example of a first signal processing circuit and processes a 5G broadcast signal. More specifically, the RFIC 3A performs signal processing, such as down-conversion, on a 5G broadcast reception signal received via the receive path of the radio-frequency circuit 1A and outputs the resulting reception signal to a BBIC.

The RFIC 3B is an example of a second signal processing circuit and processes a cellular network signal. More specifically, the RFIC 3B performs signal processing, such as down-conversion, on a cellular network signal received via the receive path of the radio-frequency circuit 1A and outputs the resulting reception signal to the BBIC. The RFIC 3B also performs signal processing, such as up-conversion, on a cellular network signal received from the BBIC and outputs the resulting transmission signal to the transmit path of the radio-frequency circuit 1A. The RFICs 3A and 3B include a controller that controls components, such as switches and amplifiers, of the radio-frequency circuit 1A. All or some of the functions of the RFICs 3A and 3B as the controller may be installed outside the RFICs 3A and 3B, such as in the BBIC or the radio-frequency circuit 1A.

The antenna 2 is not an essential component for the communication device 4A of the first modified example.

### [2.2 Circuit Configuration of Radio-Frequency Circuit 1A]

The circuit configuration of the radio-frequency circuit 1A will now be described below. As illustrated in FIG. 3, the radio-frequency circuit 1A includes filters 11, 12, and 20, switches 51, 61, and 71, a low-noise amplifier 30, a power amplifier 40, an antenna connection terminal 100, radio-frequency output terminals 111 and 112, and a radio-frequency input terminal 120.

The antenna connection terminal 100 is connected to the antenna 2 and a terminal 51a (first terminal) of the switch 51. The radio-frequency input terminal 120 is connected to the RFIC 3B and the power amplifier 40 and is used for receiving a transmission signal from the RFIC 3B. The radio-frequency output terminal 111 is connected to the RFIC 3A and a terminal 71b of the switch 71 and is used for outputting a 5G broadcast reception signal to the RFIC 3A. The radio-frequency output terminal 112 is connected to the RFIC 3B and a terminal 71c of the switch 71 and is used for outputting a cellular network signal of band A to the RFIC 3B.

The filter 11 is an example of the first filter and has a pass band including the first broadcast band for 5G broadcast. One end of the filter 11 is connected to a terminal 51b (second terminal) of the switch 51 (first switch), and the other end of the filter 11 is connected to a terminal 61a (fourth terminal) of the switch 61 (fourth switch).

The filter 20 is an example of the second filter and has a pass band including the second broadcast band for 5G broadcast and the uplink operating band of band A (first communication band: A-Tx) for cellular mobile communication. One end of the filter 20 is connected to a terminal 51d (third terminal) of the switch 51 (first switch), and the other end of the filter 20 is connected to a terminal 61c (fifth terminal) of the switch 61 (fourth switch).

The filter 12 is an example of a third filter and has a pass band including the third broadcast band for 5G broadcast and the downlink operating band of band A (second communication band: A-Rx) for cellular mobile communication. One end of the filter 12 is connected to a terminal 51c (eighth terminal) of the switch 51 (first switch), and the other end of the filter 12 is connected to a terminal 61b (ninth terminal) of the switch 61 (fourth switch).

The switch 51 is an example of the first switch and includes the terminal 51a (first terminal), terminal 51b (second terminal), terminal 51c (eighth terminal), and terminal 51d (third terminal). The switch 51 switches between the connection of the terminal 51a to the terminal 51b and the disconnection of the terminal 51a from the terminal 51b, switches between the connection of the terminal 51a to the terminal 51c and the disconnection of the terminal 51a from the terminal 51c, and switches between the connection of the terminal 51a to the terminal 51d and the disconnection of the terminal 51a from the terminal 51d. That is, the switch 51 switches between the connection of the antenna 2 to the filter 11 and the disconnection of the antenna 2 from the filter 11, switches between the connection of the antenna 2 to the filter 20 and the disconnection of the antenna 2 from the filter 20, and switches between the connection of the antenna 2 to the filter 12 and the disconnection of the antenna 2 from the filter 12.

The switch 51 may mutually exclusively perform the connection of the terminal 51a to the terminal 51b, the connection of the terminal 51a to the terminal 51c, and the connection of the terminal 51a to the terminal 51d. This enables the radio-frequency circuit 1A to selectively perform the following operations: (1) receiving a 5G broadcast signal of the first broadcast band; (2) receiving a 5G broadcast signal of the second broadcast band and/or transmitting a cellular network signal of band A; and (3) receiving a 5G broadcast signal of the third broadcast band and/or receiving a cellular network signal of band A.

The low-noise amplifier 30 is an example of the first low-noise amplifier. The input end of the low-noise amplifier 30 is connected to a terminal 61d (sixth terminal) of the switch 61, and the output end of the low-noise amplifier 30 is connected to a terminal 71a of the switch 71 (fifth switch). The low-noise amplifier 30 amplifies a 5G broadcast reception signal and a cellular network reception signal of band A input from the antenna connection terminal 100.

The power amplifier 40 is an example of the first power amplifier. The output end of the power amplifier 40 is connected to a terminal 61e (seventh terminal) of the switch 61, and the input end of the power amplifier 40 is connected to the radio-frequency input terminal 120. The power amplifier 40 amplifies a cellular network transmission signal of band A input from the radio-frequency input terminal 120.

The switch 61 is an example of a fourth switch and includes the terminal 61a (fourth terminal), terminal 61b (ninth terminal), terminal 61c (fifth terminal), terminal 61d (sixth terminal), and terminal 61e (seventh terminal). The switch 61 switches between the connection of the terminal 61d to the terminal 61a, the connection of the terminal 61d to the terminal 61c, and the connection of the terminal 61d to the terminal 61b and also switches between the connection of the terminal 61c to the terminal 61d and the connection of the terminal 61c to the terminal 61e. That is, the switch 61 performs the following switching operations: (1) switching between the connection of the low-noise amplifier 30 to the filter 11, the connection of the low-noise amplifier 30 to the filter 20, and the connection of the low-noise amplifier 30 to the filter 12; and (2) switching between the connection of the filter 20 to the low-noise amplifier 30 and the connection of the filter 20 to the power amplifier 40.

The switch 71 is an example of a fifth switch and includes terminals 71a, 71b, and 71c. The switch 71 switches between the connection of the terminal 71a to the terminal 71b and the connection of the terminal 71a to the terminal 71c. That is, the switch 71 switches between the connection of the low-noise amplifier 30 to the RFIC 3A and the connection of the low-noise amplifier 30 to the RFIC 3B.

With the above-described configuration, the radio-frequency circuit 1A is able to selectively execute the following operations: (1) amplifying a 5G broadcast reception signal of the first broadcast band; (2) amplifying a 5G broadcast reception signal of the second broadcast band; (3) amplifying a 5G broadcast reception signal of the third broadcast band; (4) amplifying a cellular network transmission signal of band A; and (5) amplifying a cellular network reception signal of band A.

### [2.3 Bandpass Characteristics of Filters 11, 12, and 20]

An explanation will now be given of the frequency bands to be applied to the radio-frequency circuit 1A of the first modified example and the signal transmission characteristics required for the radio-frequency circuit 1A.

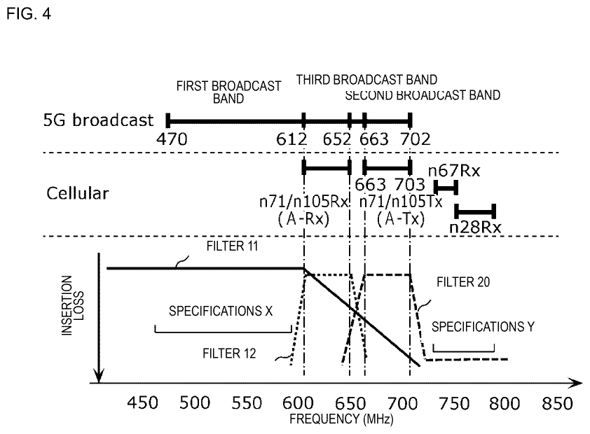

FIG. 4 is a diagram illustrating an example of the relationships between the frequency bands to be applied to the radio-frequency circuit 1A of the first modified example and an example of the bandpass characteristics of the filters 11, 12, and 20. The upper section of FIG. 4 shows the frequency bands (first broadcast band, second broadcast band, and third broadcast band) used for receiving 5G broadcast signals and communication bands (n71/n105 downlink operating band, n71/n105 uplink operating band, n67 downlink operating band, and n28 downlink operating band) allocated to cellular mobile communication.

As shown in FIG. 4, the frequency bands for receiving 5G broadcast signals by the radio-frequency circuit 1A and the communication device 4A of the first modified example are the first broadcast band, the second broadcast band, and the third broadcast band. The second broadcast band is positioned at a higher frequency side than the first broadcast band. The third broadcast band is positioned between the first broadcast band and the second broadcast band. The second broadcast band at least partially overlaps the uplink operating band of band A (first communication band) for cellular mobile communication. The third broadcast band at least partially overlaps the downlink operating band of band A (second communication band) for cellular mobile communication.

Specifications necessary for performing communication using band A are already set for 4G/5G cellular communication. It is thus necessary to satisfy specifications X for the low frequency side of band A and specifications Y for the high frequency side of band A. Specifications Y are those about the attenuation of a communication band (n67 downlink operating band, for example) located close to the high frequency side of the second broadcast band, for example.

If a 5G broadcast filter having a wide band including the first broadcast band, the second broadcast band, and the third broadcast band is to be constituted by one filter, priority has to be given to the increase in the pass band width. Prioritizing the increase in the pass band width makes it difficult to sharpen the attenuation slope at the high frequency edge of the pass band. This may fail to satisfy specifications Y regarding the attenuation of a communication band close to the high frequency side of the second broadcast band. That is, the isolation between the 5G broadcast signals and the existing cellular communication bands located close to the first broadcast band, the second broadcast band, and the third broadcast band becomes insufficient.

To address this issue, in the radio-frequency circuit 1A of the first modified example, the 5G broadcast filter is constituted by the filter 11 having the pass band including the first broadcast band, the filter 12 having the pass band including the third broadcast band, and the filter 20 having the pass band including the second broadcast band. This can secure a large frequency interval between the pass band of the filter 11 and the existing cellular communication band located close to the high frequency side of the second broadcast band. The filter 11 can thus secure the attenuation of this existing cellular communication band, in other words, it can satisfy specifications Y. Regarding the filter 20 having the pass band including the second broadcast band, a filter having a pass band including the uplink operating band of band A, which is an existing cellular communication band, can be used as the filter 20. The filter 20 does not increase the pass band width and can thus secure a sufficient attenuation of the existing cellular communication band close to the second broadcast band. Regarding the filter 12 having the pass band including the third broadcast band, a filter having a pass band including the downlink operating band of band A, which is an existing cellular communication band, can be used as the filter 12. The filter 12 does not increase the pass band width and can thus secure a sufficient attenuation of the existing cellular communication band close to the second broadcast band. Hence, the radio-frequency circuit 1A is able to receive a 5G broadcast signal while reducing interference with a cellular communication band.

The filter 11 used for 5G broadcast does not need to increase the pass band width and can thus be reduced in size. The filter 20 can be used both for an existing cellular communication band and the second broadcast band for 5G broadcast. The filter 12 can be used both for an existing cellular communication band and the third broadcast band for 5G broadcast. It is thus possible to provide a small radio-frequency circuit 1A that can receive a 5G broadcast signal and also transmit and receive band A for cellular communication.

The filter 11 may be an LC filter including an inductor and a capacitor. There is a large frequency interval between the pass band of the filter 11 and that of the existing cellular communication band close to the second broadcast band. The filter 11 can thus be formed by a low-loss and small-sized LC filter.

The filters 12 and 20 may be acoustic wave filters including acoustic wave resonators. The filters 12 and 20 having a small frequency interval with the existing cellular communication band close to the second broadcast band are formed by acoustic wave filters, thereby making it possible to secure a large attenuation of this existing cellular communication band.

As illustrated in FIG. 4, in the radio-frequency circuit 1A of the first modified example, the first broadcast band is 470 to 612 MHz, the second broadcast band is 663 to 702 MHZ, and the third broadcast band is 612 to 652 MHz. The uplink operating band of band A (first communication band) is one of the uplink operating band of band 71 or band 105 for 4G-LTE and the uplink operating band of band n71 or band n105 for 5G-NR. The downlink operating band of band A (second communication band) is one of the downlink operating band of band 71 or band 105 for 4G-LTE and the downlink operating band of band n71 or band n105 for 5G-NR.

### 3 Circuit Configurations of Radio-Frequency Circuit 1B and Communication Device 4B of Second Modified Example

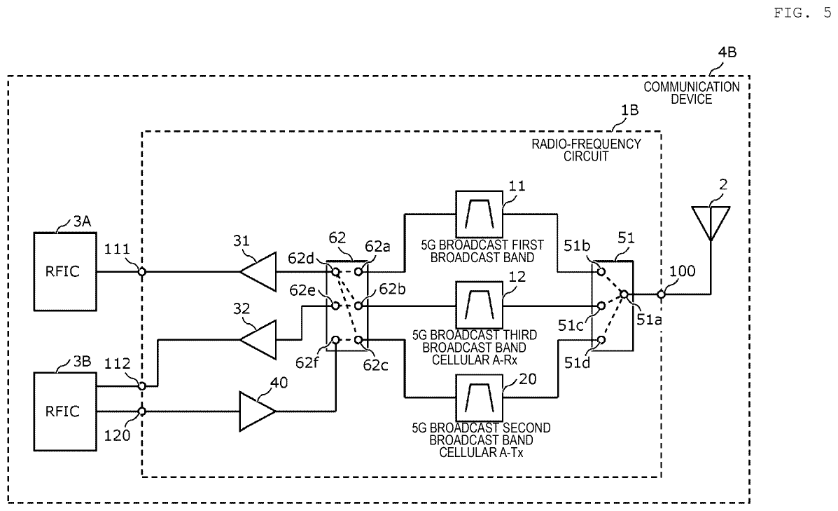

The circuit configurations of a radio-frequency circuit 1B and a communication device 4B according to a second modified example of the embodiment will be described below with reference to FIG. 5. FIG. 5 is a circuit diagram of the radio-frequency circuit 1B and the communication device 4B according to the second modified example of the embodiment.

### [3.1 Circuit Configuration of Communication Device 4B]

As illustrated in FIG. 5, the communication device 4B according to the second modified example includes the radio-frequency circuit 1B, an antenna 2, and RFICs 3A and 3B. The communication device 4B of the second modified example is different from the communication device 4A of the first modified example only in that the configuration of the radio-frequency circuit 1B is different from that of the radio-frequency circuit 1A of the first modified example. An explanation will thus be given of the circuit configuration of the radio-frequency circuit 1B.

### [3.2 Circuit Configuration of Radio-Frequency Circuit 1B]

As illustrated in FIG. 5, the radio-frequency circuit 1B includes filters 11, 12, and 20, switches 51 and 62, low-noise amplifiers 31 and 32, a power amplifier 40, an antenna connection terminal 100, radio-frequency output terminals 111 and 112, and a radio-frequency input terminal 120. The radio-frequency circuit 1B of the second modified example is different from the radio-frequency circuit 1A of the first modified example mainly in the configuration of the low-noise amplifiers. The radio-frequency circuit 1B of the second modified example will be described below by mainly referring to the points different from the radio-frequency circuit 1A of the first modified example while omitting an explanation of the same points as those of the radio-frequency circuit 1A.

One end of the filter 11 is connected to a terminal 51b (second terminal) of the switch 51 (first switch), and the other end of the filter 11 is connected to a terminal 62a (fourth terminal) of the switch 62 (sixth switch). One end of the filter 20 is connected to a terminal 51d (third terminal) of the switch 51 (first switch), and the other end of the filter 20 is connected to a terminal 62c (fifth terminal) of the switch 62 (sixth switch). One end of the filter 12 is connected to a terminal 51c (eighth terminal) of the switch 51 (first switch), and the other end of the filter 12 is connected to a terminal 62b (ninth terminal) of the switch 62 (sixth switch).

The low-noise amplifier 31 is an example of the first low-noise amplifier. The input end of the low-noise amplifier 31 is connected to a terminal 62d (sixth terminal) of the switch 62, and the output end of the low-noise amplifier 31 is connected to the radio-frequency output terminal 111. The low-noise amplifier 31 amplifies a 5G broadcast reception signal input from the antenna connection terminal 100.

The low-noise amplifier 32 is an example of a second low-noise amplifier. The input end of the low-noise amplifier 32 is connected to a terminal 62e (tenth terminal) of the switch 62, and the output end of the low-noise amplifier 32 is connected to the radio-frequency output terminal 112. The low-noise amplifier 32 amplifies a cellular network reception signal of band A input from the antenna connection terminal 100.

The output end of the power amplifier 40 is connected to a terminal 62f (seventh terminal) of the switch 62, and the input end of the power amplifier 40 is connected to the radio-frequency input terminal 120. The power amplifier 40 amplifies a cellular network transmission signal of band A input from the radio-frequency input terminal 120.

The switch 62 is an example of a sixth switch and includes the terminal 62a (fourth terminal), terminal 62b (ninth terminal), terminal 62c (fifth terminal), terminal 62d (sixth terminal), terminal 62e (tenth terminal), and terminal 62f (seventh terminal). The switch 62 switches between the connection of the terminal 62d to the terminal 62a, the connection of the terminal 62d to the terminal 62c, and the connection of the terminal 62d to the terminal 62b, switches between the connection of the terminal 62b to the terminal 62d and the connection of the terminal 62b to the terminal 62e, and switches between the connection of the terminal 62c to the terminal 62d and the connection of the terminal 62c to the terminal 62f. That is, the switch 62 performs the following switching operations: (1) switching between the connection of the low-noise amplifier 31 to the filter 11, the connection of the low-noise amplifier 31 to the filter 20, and the connection of the low-noise amplifier 31 to the filter 12; (2) switching between the connection of the filter 12 to the low-noise amplifier 31 and the connection of the filter 12 to the low-noise amplifier 32; and (3) switching between the connection of the filter 20 to the low-noise amplifier 31 and the connection of the filter 20 to the power amplifier 40.

With the above-described configuration, in the radio-frequency circuit 1B, the low-noise amplifier 31 can be used as a dedicated amplifier for 5G broadcast, while the low-noise amplifier 32 can be used as a dedicated amplifier for cellular network communication. The radio-frequency circuit 1B is able to selectively execute the following operations: (1) amplifying a 5G broadcast reception signal of the first broadcast band; (2) amplifying a 5G broadcast reception signal of the second broadcast band; (3) amplifying a 5G broadcast reception signal of the third broadcast band; (4) amplifying a cellular network transmission signal of the uplink operating band of band A; and (5) amplifying a cellular network reception signal of the downlink operating band of band A.

### 4 Circuit Configuration of Radio-Frequency Circuit 1C of Third Modified Example

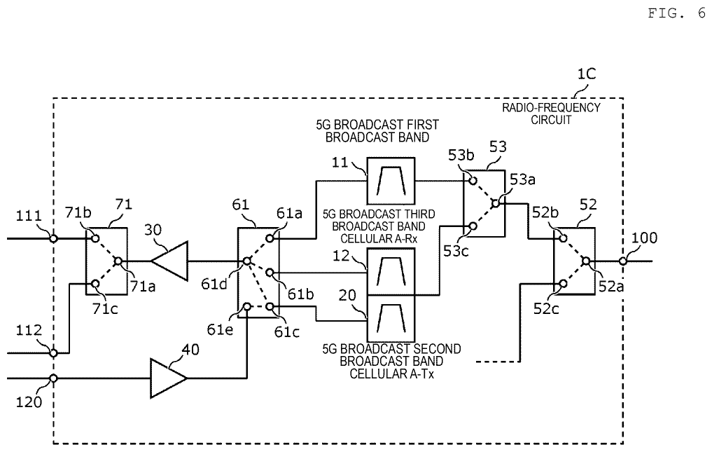

The circuit configuration of a radio-frequency circuit 1C of a third modified example of the embodiment will now be described below with reference to FIG. 6. FIG. 6 is a circuit diagram of the radio-frequency circuit 1C according to the third modified example of the embodiment.

As illustrated in FIG. 6, the radio-frequency circuit 1C includes filters 11, 12, and 20, switches 52, 53, 61, and 71, a low-noise amplifier 30, a power amplifier 40, an antenna connection terminal 100, radio-frequency output terminals 111 and 112, and a radio-frequency input terminal 120. The radio-frequency circuit 1C of the third modified example is different from the radio-frequency circuit 1A of the first modified example mainly in the connection configuration between the filters 12 and 20 and the antenna connection terminal 100. The radio-frequency circuit 1C of the third modified example will be described below by mainly referring to the points different from the radio-frequency circuit 1A of the first modified example while omitting an explanation of the same points as those of the radio-frequency circuit 1A.

The antenna connection terminal 100 is connected to a terminal 52a of the switch 52. The radio-frequency input terminal 120 is connected to the power amplifier 40 and is used for receiving a transmission signal from the RFIC 3B. The radio-frequency output terminal 111 is connected to a terminal 71b of the switch 71 and is used for outputting a 5G broadcast reception signal to the RFIC 3A. The radio-frequency output terminal 112 is connected to a terminal 71c of the switch 71 and is used for outputting a cellular network signal of band A to the RFIC 3B.

One end of the filter 11 is connected to a terminal 53b of the switch 53, and the other end of the filter 11 is connected to a terminal 61a (fourth terminal) of the switch 61 (fourth switch).

One end of the filter 20 is connected to a terminal 53c of the switch 53, and the other end of the filter 20 is connected to a terminal 61c (fifth terminal) of the switch 61 (fourth switch).

One end of the filter 12 is connected to the terminal 53c of the switch 53, and the other end of the filter 12 is connected to a terminal 61b (ninth terminal) of the switch 61 (fourth switch).

The switch 53 includes terminals 53a, 53b, and 53c. The switch 53 switches between the connection of the terminal 53a to the terminal 53b and the disconnection of the terminal 53a from the terminal 53b and also switches between the connection of the terminal 53a to the terminal 53c and the disconnection of the terminal 53a from the terminal 53c. That is, the switch 53 switches between the connection of the antenna 2 to the filter 11 and the disconnection of the antenna 2 from the filter 11 and switches between the connection of the antenna 2 to the filters 12 and 20 and the disconnection of the antenna 2 from the filters 12 and 20.

The switch 52 includes terminals 52a, 52b, and 52c. The switch 52 switches between the connection of the terminal 52a to the terminal 52b and the disconnection of the terminal 52a from the terminal 52b and also switches between the connection of the terminal 52a to the terminal 52c and the disconnection of the terminal 52a from the terminal 52c. The terminal 52b is connected to the terminal 53a. The terminal 52c is connected to a filter having a pass band including a cellular communication band, for example. The switch 52 may be omitted from the radio-frequency circuit 1C of the third modified example. In this case, the terminal 53a of the switch 53 is connected to the antenna connection terminal 100.

In the third modified example, the filters 12 and 20 form a duplexer for band A, which is a cellular communication band. The input end of the filter 12 and the output end of the filter 20 are connected to the same terminal, that is, the terminal 53c.

With the above-described configuration, the radio-frequency circuit 1C is able to selectively perform the following operations: (1) receiving a 5G broadcast signal of the first broadcast band; (2) receiving a 5G broadcast signal of the second broadcast band; (3) receiving a 5G broadcast signal of the third broadcast band; and (4) transmitting and receiving a cellular network signal of band A.

The input end of the filter 12 and the output end of the filter 20 are connected to the same terminal, that is, the terminal 53c. This can reduce the number of terminals of the switch 53 and thus reduce the size of the radio-frequency circuit 1C.

### 5 Circuit Configurations of Radio-Frequency Circuit 1D and Communication Device 4D of Fourth Modified Example

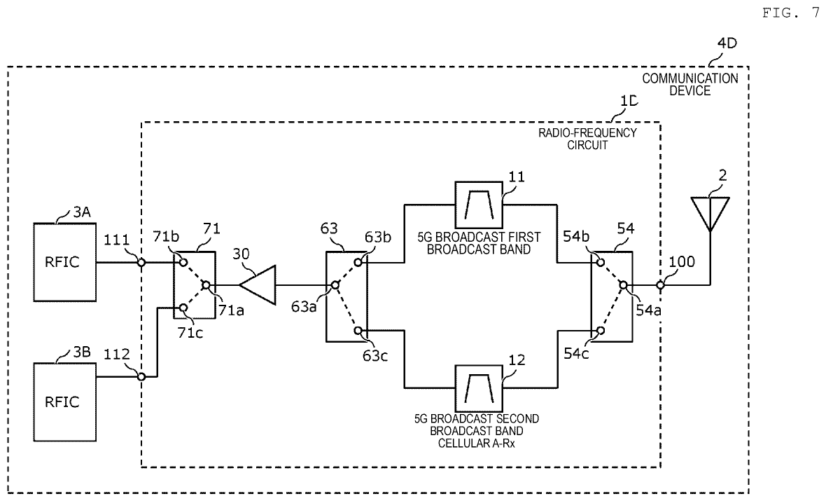

The circuit configurations of a radio-frequency circuit 1D and a communication device 4D according to a fourth modified example of the embodiment will be described below with reference to FIG. 7. FIG. 7 is a circuit diagram of the radio-frequency circuit 1D and the communication device 4D according to the fourth modified example of the embodiment.

### [5.1 Circuit Configuration of Communication Device 4D]

As illustrated in FIG. 7, the communication device 4D according to the fourth modified example includes the radio-frequency circuit 1D, an antenna 2, and RFICs 3A and 3B. The communication device 4D of the fourth modified example is different from the communication device 4A of the first modified example only in that the configuration of the radio-frequency circuit 1D is different from that of the radio-frequency circuit 1A of the first modified example.

An explanation will thus be given of the circuit configuration of the radio-frequency circuit 1D.

### [5.2 Circuit Configuration of Radio-Frequency Circuit 1D]

As illustrated in FIG. 7, the radio-frequency circuit 1D includes filters 11 and 12, switches 54, 63, and 71, a low-noise amplifier 30, an antenna connection terminal 100, and radio-frequency output terminals 111 and 112. The radio-frequency circuit 1D of the fourth modified example is different from the radio-frequency circuit 1A of the first modified example mainly in that the filter 20 and the power amplifier 40 are not provided. The radio-frequency circuit 1D of the fourth modified example will be described below by mainly referring to the points different from the radio-frequency circuit 1A of the first modified example while omitting an explanation of the same points as those of the radio-frequency circuit 1A.

The antenna connection terminal 100 is connected to the antenna 2 and a terminal 54a (first terminal) of the switch 54 (first switch). The radio-frequency output terminal 111 is connected to the RFIC 3A and a terminal 71b of the switch 71 and is used for outputting a 5G broadcast reception signal to the RFIC 3A. The radio-frequency output terminal 112 is connected to the RFIC 3B and a terminal 71c of the switch 71 and is used for outputting a cellular network signal of band A to the RFIC 3B.

The filter 11 is an example of the first filter and has a pass band including the first broadcast band for 5G broadcast. One end of the filter 11 is connected to a terminal 54b (second terminal) of the switch 54 (first switch), and the other end of the filter 11 is connected to a terminal 63b (fourth terminal) of the switch 63 (third switch).

The filter 12 is an example of the second filter and has a pass band including the second broadcast band for 5G broadcast and the downlink operating band of band A (first communication band: A-Rx) for cellular mobile communication. One end of the filter 12 is connected to a terminal 54c (third terminal) of the switch 54 (first switch), and the other end of the filter 12 is connected to a terminal 63c (fifth terminal) of the switch 63 (third switch).

The switch 54 is an example of the first switch and includes the terminal 54a (first terminal), terminal 54b (second terminal), and terminal 54c (third terminal). The switch 54 switches between the connection of the terminal 54a to the terminal 54b and the disconnection of the terminal 54a from the terminal 54b and switches between the connection of the terminal 54a to the terminal 54c and the disconnection of the terminal 54a from the terminal 54c. That is, the switch 54 switches between the connection of the antenna 2 to the filter 11 and the disconnection of the antenna 2 from the filter 11 and switches between the connection of the antenna 2 to the filter 12 and the disconnection of the antenna 2 from the filter 12.

The switch 54 may mutually exclusively perform the connection of the terminal 54a to the terminal 54b and the connection of the terminal 54a to the terminal 54c. This enables the radio-frequency circuit 1D to selectively perform the following operations: (1) receiving a 5G broadcast signal of the first broadcast band; and (2) receiving a 5G broadcast signal of the second broadcast band and/or receiving a cellular network signal of band A.

The low-noise amplifier 30 is an example of the first low-noise amplifier. The input end of the low-noise amplifier 30 is connected to a terminal 63a (sixth terminal) of the switch 63, and the output end of the low-noise amplifier 30 is connected to a terminal 71a of the switch 71 (fifth switch). The low-noise amplifier 30 amplifies a 5G broadcast reception signal and a cellular network reception signal of band A input from the antenna connection terminal 100.

The switch 63 is an example of a third switch and includes the terminal 63a (sixth terminal), terminal 63b (fourth terminal), and terminal 63c (fifth terminal). The switch 63 switches between the connection of the terminal 63a to the terminal 63b and the connection of the terminal 63a to the terminal 63c. That is, the switch 63 switches between the connection of the low-noise amplifier 30 to the filter 11 and the connection of the low-noise amplifier 30 to the filter 12.

The switch 71 is an example of the fifth switch and includes the terminals 71a, 71b, and 71c. The switch 71 switches between the connection of the terminal 71a to the terminal 71b and the connection of the terminal 71a to the terminal 71c. That is, the switch 71 switches between the connection of the low-noise amplifier 30 to the RFIC 3A and the connection of the low-noise amplifier 30 to the RFIC 3B.

With the above-described configuration, the radio-frequency circuit 1D is able to selectively execute the following operations: (1) amplifying a 5G broadcast reception signal of the first broadcast band; (2) amplifying a 5G broadcast reception signal of the second broadcast band; and (3) amplifying a cellular network reception signal of band A.

### [5.3 Bandpass Characteristics of Filters 11 and 12]

An explanation will now be given of the frequency bands to be applied to the radio-frequency circuit 1D of the fourth modified example and the signal transmission characteristics required for the radio-frequency circuit 1D.

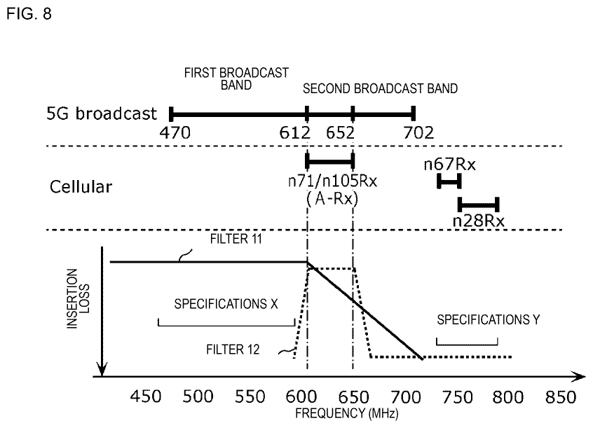

FIG. 8 is a diagram illustrating an example of the relationships between the frequency bands to be applied to the radio-frequency circuit 1D of the fourth modified example and an example of the bandpass characteristics of the filters 11 and 12. The upper section of FIG. 8 shows the frequency bands (first broadcast band and second broadcast band) used for receiving 5G broadcast signals and communication bands (n71/n105 downlink operating band, n67 downlink operating band, and n28 downlink operating band) allocated to cellular mobile communication.

As shown in FIG. 8, the frequency bands for receiving 5G broadcast signals by the radio-frequency circuit 1D and the communication device 4D of the fourth modified example are the first broadcast band and the second broadcast band. The second broadcast band is positioned at a higher frequency side than the first broadcast band. The second broadcast band at least partially overlaps the downlink operating band of band A (first communication band) for cellular mobile communication.

Specifications necessary for performing communication using band A are already set for 4G/5G cellular communication. It is thus necessary to satisfy specifications X for the low frequency side of band A and specifications Y for the high frequency side of band A. Specifications Y are those about the attenuation of a communication band (n67 downlink operating band, for example) located close to the high frequency side of the second broadcast band, for example.

If a 5G broadcast filter having a wide band including the first broadcast band and the second broadcast band is to be constituted by one filter, priority has to be given to the increase in the pass band width. Prioritizing the increase in the pass band width makes it difficult to sharpen the attenuation slope at the high frequency edge of the pass band. This may fail to satisfy specifications Y regarding the attenuation of a communication band close to the high frequency side of the second broadcast band. That is, the isolation between the 5G broadcast signals and the existing cellular communication band located close to the second broadcast band becomes insufficient.

To address this issue, in the radio-frequency circuit 1D of the fourth modified example, the 5G broadcast filter is constituted by the filter 11 having the pass band including the first broadcast band and the filter 12 having the pass band including the second broadcast band. This can secure a large frequency interval between the pass band of the filter 11 and the existing cellular communication band located close to the high frequency side of the second broadcast band. The filter 11 can thus secure the attenuation of this existing cellular communication band, in other words, it can satisfy specifications Y. Regarding the filter 12 having the pass band including the second broadcast band, a filter having a pass band including the downlink operating band of band A, which is an existing cellular communication band, can be used as the filter 12. The filter 12 does not increase the pass band width and can thus secure a sufficient attenuation of the existing cellular communication band close to the second broadcast band. Hence, the radio-frequency circuit 1D is able to receive a 5G broadcast signal while reducing interference with a cellular communication band.

The filter 11 used for 5G broadcast does not need to increase the pass band width and can thus be reduced in size. The filter 12 can be used both for an existing cellular communication band and the second broadcast band for 5G broadcast. It is thus possible to provide a small radio-frequency circuit 1D that can receive a 5G broadcast signal and also receive band A for cellular communication.

As illustrated in FIG. 8, in the radio-frequency circuit 1D of the fourth modified example, the first broadcast band is 470 to 612 MHz, and the second broadcast band is 612 to 652 MHZ. The downlink operating band of band A (first communication band) is one of the downlink operating band of band 71 or band 105 for 4G-LTE and the downlink operating band of band n71 or band n105 for 5G-NR.

### 6 Circuit Configurations of Radio-Frequency Circuit 1E and Communication Device 4E of Fifth Modified Example

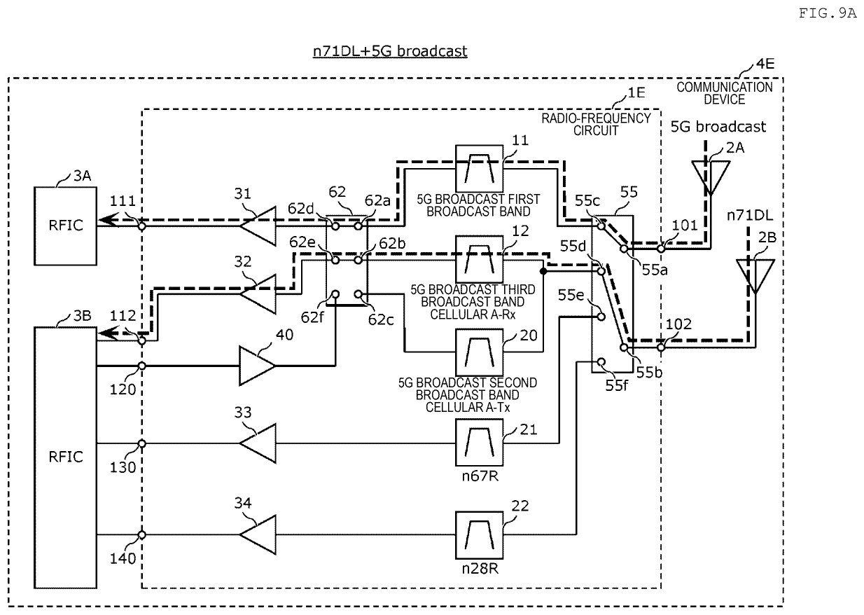

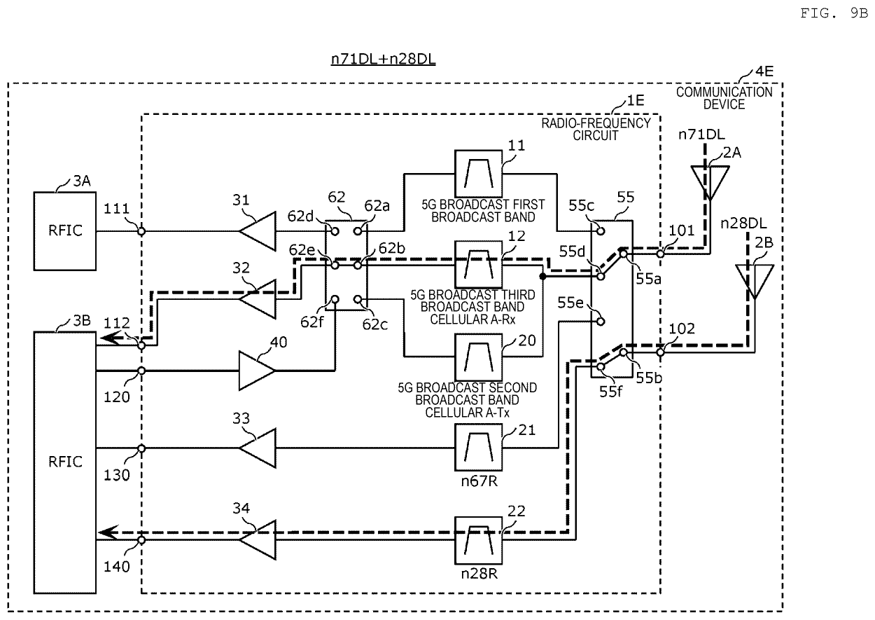

The circuit configurations of a radio-frequency circuit 1E and a communication device 4E according to a fifth modified example of the embodiment will be described below with reference to FIGS. 9A and 9B. FIG. 9A is a circuit state diagram illustrating a first signal transmission state of the radio-frequency circuit 1E and the communication device 4E according to the fifth modified example. FIG. 9B is a circuit state diagram illustrating a second signal transmission state of the radio-frequency circuit 1E and the communication device 4E according to the fifth modified example.

### [6.1 Circuit Configuration of Communication Device 4E]

As illustrated in FIGS. 9A and 9B, the communication device 4E according to the fifth modified example includes the radio-frequency circuit 1E, antennas 2A and 2B, and RFICs 3A and 3B. The communication device 4E of the fifth modified example is different from the communication device 4B of the second modified example in that the configurations of the radio-frequency circuit 1E and the antennas 2A and 2B are different from those of the radio-frequency circuit 1B and the antenna 2 of the second modified example. An explanation will be given of the circuit configurations of the radio-frequency circuit 1E and the antennas 2A and 2B.

The antenna 2A is an example of a first antenna. The antenna 2A is connected to an antenna connection terminal 101 of the radio-frequency circuit 1E. The antenna 2A is able to transmit a 5G broadcast transmission signal and a cellular network transmission signal output from the radio-frequency circuit 1E and also to receive a 5G broadcast reception signal and a cellular network reception signal from an external source and output these signals to the radio-frequency circuit 1E.

The antenna 2B is an example of a second antenna. The antenna 2B is connected to an antenna connection terminal 102 of the radio-frequency circuit 1E. The antenna 2B is able to transmit a cellular network transmission signal output from the radio-frequency circuit 1E and also to receive a cellular network reception signal from an external source and output the cellular network reception signal to the radio-frequency circuit 1E. The antenna 2B may also be able to receive a 5G broadcast reception signal.

### [6.2 Circuit Configuration of Radio-Frequency Circuit 1E]

As illustrated in FIGS. 9A and 9B, the radio-frequency circuit 1E includes filters 11, 12, 20, 21, and 22, switches 55 and 62, low-noise amplifiers 31, 32, 33, and 34, a power amplifier 40, antenna connection terminals 101 and 102, radio-frequency output terminals 111, 112, 130, and 140, and a radio-frequency input terminal 120. The radio-frequency circuit 1E of the fifth modified example is different from the radio-frequency circuit 1B of the second modified example mainly in that filters and low-noise amplifiers for cellular communication bands are added. The radio-frequency circuit 1E of the fifth modified example will be described below by mainly referring to the points different from the radio-frequency circuit 1B of the second modified example while omitting an explanation of the same points as those of the radio-frequency circuit 1B.

The antenna connection terminal 101 is connected to the antenna 2A and a terminal 55a (first terminal) of the switch 55. The antenna connection terminal 102 is connected to the antenna 2B and a terminal 55b (eleventh terminal) of the switch 55. The radio-frequency input terminal 120 is connected to the RFIC 3B and the power amplifier 40 and is used for receiving a transmission signal from the RFIC 3B. The radio-frequency output terminal 111 is connected to the RFIC 3A and the output end of the low-noise amplifier 31 and is used for outputting a 5G broadcast reception signal to the RFIC 3A. The radio-frequency output terminal 112 is connected to the RFIC 3B and the output end of the low-noise amplifier 32 and is used for outputting a cellular network signal of band A to the RFIC 3B. The radio-frequency output terminal 130 is connected to the RFIC 3B and the output end of the low-noise amplifier 33 and is used for outputting a cellular network reception signal of the fourth communication band to the RFIC 3B. The radio-frequency output terminal 140 is connected to the RFIC 3B and the output end of the low-noise amplifier 34 and is used for outputting a cellular network reception signal of the third communication band to the RFIC 3B.

The filter 11 is an example of the first filter and has a pass band including the first broadcast band for 5G broadcast. One end of the filter 11 is connected to a terminal 55c (second terminal) of the switch 55 (first switch), and the other end of the filter 11 is connected to a terminal 62a of the switch 62.

The filter 20 is an example of the second filter and has a pass band including the second broadcast band for 5G broadcast and the uplink operating band of band A (first communication band: A-Tx) for cellular mobile communication. One end of the filter 20 is connected to a terminal 55d (third terminal) of the switch 55 (first switch), and the other end of the filter 20 is connected to a terminal 62c of the switch 62.

The filter 12 is an example of the third filter and has a pass band including the third broadcast band for 5G broadcast and the downlink operating band of band A (second communication band: A-Rx) for cellular mobile communication. One end of the filter 12 is connected to the terminal 55d (eighth terminal) of the switch 55 (first switch), and the other end of the filter 12 is connected to a terminal 62b of the switch 62.

One end of the filter 20 and one end of the filter 12 are connected to the same terminal, that is, the terminal 55d of the switch 55, but they may be connected to different terminals of the switch 55.

The filter 21 has a pass band including the fourth communication band (downlink operating band) for cellular mobile communication. One end of the filter 21 is connected to the terminal 55e of the switch 55 (first switch), and the other end of the filter 21 is connected to the input end of the low-noise amplifier 33.

The filter 22 is an example of a fourth filter and has a pass band including the third communication band (downlink operating band) for cellular mobile communication. One end of the filter 22 is connected to a terminal 55f (twelfth terminal) of the switch 55 (first switch), and the other end of the filter 22 is connected to the input end of the low-noise amplifier 34.

The switch 55 is an example of the first switch and includes the terminal 55a (first terminal), terminal 55b (eleventh terminal), terminal 55c (second terminal), terminal 55d (third and eighth terminals), terminal 55e, and terminal 55f (twelfth terminal).

The second broadcast band for 5G broadcast is positioned between the third communication band for cellular mobile communication and the third broadcast band for 5G broadcast.

The input end of the low-noise amplifier 33 is connected to the other end of the filter 21, and the output end of the low-noise amplifier 33 is connected to the radio-frequency output terminal 130. The low-noise amplifier 33 amplifies a cellular network reception signal of the fourth communication band input from the antenna connection terminal 101 or 102.

The input end of the low-noise amplifier 34 is connected to the other end of the filter 22, and the output end of the low-noise amplifier 34 is connected to the radio-frequency output terminal 140. The low-noise amplifier 34 amplifies a cellular network reception signal of the third communication band input from the antenna connection terminal 101 or 102.

With the above-described configuration, the radio-frequency circuit 1E is able to selectively perform the following operations: (1) receiving a 5G broadcast signal of the first broadcast band; (2) receiving a 5G broadcast signal of the second broadcast band and/or transmitting a cellular network signal of band A; (3) receiving a 5G broadcast signal of the third broadcast band and/or receiving a cellular network signal of band A; (4) receiving a cellular network signal of the fourth communication band; and (5) receiving a cellular network signal of the third communication band.

The radio-frequency circuit 1E is also able to perform the following operations: (6) simultaneously receiving a 5G broadcast signal of the first broadcast band and a cellular network signal of the downlink operating band of band A; and (7) simultaneously receiving a cellular network signal of the downlink operating band of band A and a cellular network signal of the third communication band.

The operation (6) of simultaneously receiving a 5G broadcast signal of the first broadcast band and a cellular network signal of the downlink operating band of band A will be discussed more specifically. As shown in FIG. 9A, the terminals 55a and 55c of the switch 55 are connected to each other, and the terminals 55b and 55d of the switch 55 are also connected to each other. Additionally, the terminals 62a and 62d of the switch 62 are connected to each other, and the terminals 62b and 62e of the switch 62 are connected to each other. With the connection of the above-described terminals of the switches 55 and 62, a 5G broadcast signal of the first broadcast band (represented by “5G broadcast” in FIG. 9A) is output to the RFIC 3A via the antenna 2A, antenna connection terminal 101, switch 55, filter 11, switch 62, low-noise amplifier 31, and radio-frequency output terminal 111. A cellular network signal of the downlink operating band of band A (represented by “n71DL” in FIG. 9A) is output to the RFIC 3B via the antenna 2B, antenna connection terminal 102, switch 55, filter 12, switch 62, low-noise amplifier 32, and radio-frequency output terminal 112.

The operation (7) of simultaneously receiving a cellular network signal of the downlink operating band of band A and a cellular network signal of the third communication band will be discussed more specifically. As shown in FIG. 9B, the terminals 55a and 55d of the switch 55 are connected to each other, and the terminals 55b and 55f of the switch 55 are also connected to each other. Additionally, the terminals 62b and 62e of the switch 62 are connected to each other. With the connection of the above-described terminals of the switches 55 and 62, a cellular network signal of the downlink operating band of band A (represented by “n71DL” in FIG. 9B) is output to the RFIC 3B via the antenna 2A, antenna connection terminal 101, switch 55, filter 12, switch 62, low-noise amplifier 32, and radio-frequency output terminal 112. A cellular network signal of the third communication band (represented by “n28DL” in FIG. 9B) is output to the RFIC 3B via the antenna 2B, antenna connection terminal 102, switch 55, filter 22, low-noise amplifier 34, and radio-frequency output terminal 140.

As illustrated in FIGS. 9A and 9B, in the radio-frequency circuit 1E of the fifth modified example, the first broadcast band is 470 to 612 MHz, the second broadcast band is 663 to 702 MHZ, and the third broadcast band is 612 to 652 MHz. The uplink operating band of band A (first communication band) is one of the uplink operating band of band 71 or band 105 for 4G-LTE and the uplink operating band of band n71 or band n105 for 5G-NR. The downlink operating band of band A (second communication band) is one of the downlink operating band of band 71 or band 105 for 4G-LTE and the downlink operating band of band n71 or band n105 for 5G-NR. The third communication band is one of the downlink operating band of band 28 for 4G-LTE and the downlink operating band of band n28 for 5G-NR. The fourth communication band is one of the downlink operating band of band 67 for 4G-LTE and the downlink operating band of band n67 for 5G-NR.

### 7 Circuit Configurations of Radio-Frequency Circuit 1F and Communication Device 4F of Sixth Modified Example

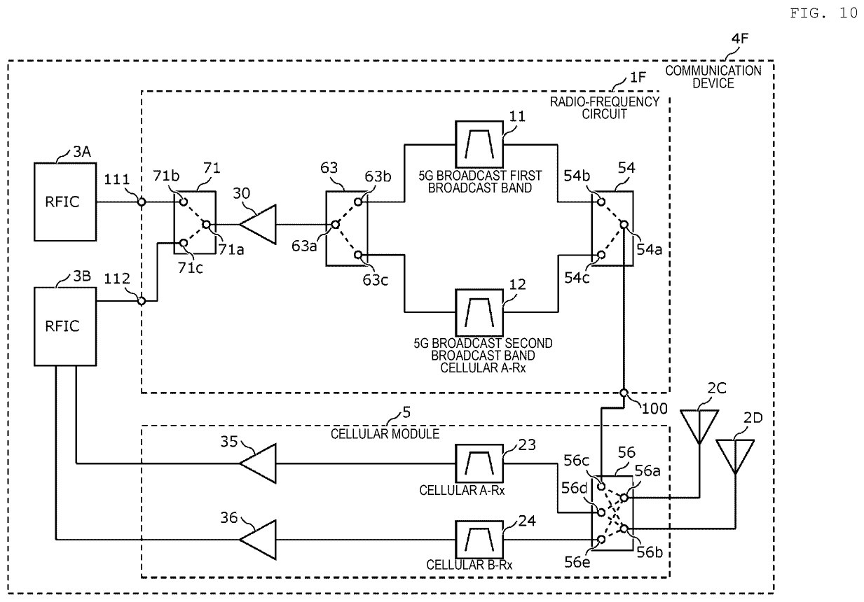

The circuit configurations of a radio-frequency circuit 1F and a communication device 4F according to a sixth modified example of the embodiment will be described below with reference to FIG. 10. FIG. 10 is a circuit diagram of the radio-frequency circuit 1F and the communication device 4F according to the sixth modified example of the embodiment.

### [7.1 Circuit Configuration of Communication Device 4F]

As illustrated in FIG. 10, the communication device 4F according to the sixth modified example includes the radio-frequency circuit 1F, a cellular module 5, antennas 2C and 2D, and RFICs 3A and 3B. The communication device 4F of the sixth modified example is different from the communication device 4D of the fourth modified example in that the cellular module 5 is added and the connection configuration between the radio-frequency circuit 1F and the antennas 2C and 2D is different from that of the radio-frequency circuit 1D and the antenna 2 of the fourth modified example. An explanation will be given of the circuit configuration of the cellular module 5 and the connection configuration of the radio-frequency circuit 1F to the antennas 2C and 2D.

The antennas 2C and 2D are connected to a switch 56 of the cellular module 5. The antennas 2C and 2D can receive a 5G broadcast reception signal from an external source and output it to the radio-frequency circuit 1F via the switch 56. The antennas 2C and 2D can also receive a cellular network reception signal and output it to the cellular module 5.

### [7.2 Circuit Configuration of Radio-Frequency Circuit 1F]

As illustrated in FIG. 10, the radio-frequency circuit 1F includes filters 11 and 12, switches 54, 63, and 71, a low-noise amplifier 30, an antenna connection terminal 100, and radio-frequency output terminals 111 and 112. The radio-frequency circuit 1F of the sixth modified example is different from the radio-frequency circuit 1D of the fourth modified example only in that the antenna connection terminal 100 is connected to a component different from that in the radio-frequency circuit 1D. The radio-frequency circuit 1F of the sixth modified example will be described below by mainly referring to the points different from the radio-frequency circuit 1D of the fourth modified example while omitting an explanation of the same points as those of the radio-frequency circuit 1D.

The antenna connection terminal 100 is an external connection terminal connected to the switch 56 of the cellular module 5, which is an independent component different from the radio-frequency circuit 1F.

### [7.3 Circuit Configuration of Cellular Module 5]

The cellular module 5 is a module that transfers a cellular network signal for cellular mobile communication. The cellular module 5 is an independent component different from the radio-frequency circuit 1F. More specifically, filters 23 and 24, low-noise amplifiers 35 and 36, and the switch 56 that form the cellular module 5 are disposed on a single module laminate, and the circuit components forming the radio-frequency circuit 1F are not disposed on this module laminate.

The filter 23 is an example of a fifth filter and has a pass band including the downlink operating band of band A (first communication band: A-Rx) for cellular mobile communication. One end of the filter 23 is connected to a terminal 56d of the switch 56 (seventh switch), and the other end of the filter 23 is connected to the input end of the low-noise amplifier 35.

The filter 24 has a pass band including the downlink operating band of band B (B-Rx) for cellular mobile communication. One end of the filter 24 is connected to a terminal 56e of the switch 56 (seventh switch), and the other end of the filter 24 is connected to the input end of the low-noise amplifier 36.

The input end of the low-noise amplifier 35 is connected to the other end of the filter 23, and the output end of the low-noise amplifier 35 is connected to the RFIC 3B. The low-noise amplifier 35 amplifies a cellular network reception signal of band A input from the antenna 2C or 2D.

The input end of the low-noise amplifier 36 is connected to the other end of the filter 24, and the output end of the low-noise amplifier 36 is connected to the RFIC 3B. The low-noise amplifier 36 amplifies a cellular network reception signal of band B input from the antenna 2C or 2D.

The switch 56 is an example of a seventh switch and includes terminals 56a, 56b, 56c, 56d, and 56e. The terminal 56a is connected to the antenna 2C. The terminal 56b is connected to the antenna 2D. The terminal 56c is connected to the antenna connection terminal 100 of the radio-frequency circuit 1F. The terminal 56d is connected to the filter 23. The terminal 56e is connected to the filter 24. With the above-described connection configuration, the switch 56 can perform the following switching operations: (1) switching between the connection of the antenna 2C to the antenna connection terminal 100, the connection of the antenna 2C to the filter 23, and the connection of the antenna 2C to the filter 24; and (2) switching between the connection of the antenna 2D to the antenna connection terminal 100, the connection of the antenna 2D to the filter 23, and the connection of the antenna 2D to the filter 24.

With the above-described configuration, the communication device 4F can receive a 5G broadcast signal of the first broadcast band and a 5G broadcast signal of the second broadcast band by the antennas 2C and 2D and transfer these signals to the radio-frequency circuit 1F. The communication device 4F can also receive a 5G broadcast signal of the first broadcast band and a 5G broadcast signal of the second broadcast band by one of the antennas 2C and 2D and transfer these signals to the radio-frequency circuit 1F and at the same time receive a cellular network signal of band A and a cellular network signal of band B by the other one of the antennas 2C and 2D and transfer these signals to the cellular module 5.

This makes it possible to receive a 5G broadcast signal by using the antenna used for cellular communication. It is thus possible to provide a small communication device 4F that can be used both for 5G broadcast reception and cellular communication using the first communication band.

The cellular module 5 may include a filter having a pass band including the uplink operating band of a communication band for cellular mobile communication and a power amplifier connected to this filter. Communication bands that the cellular module 5 can support are not limited to the downlink operating band of band A (A-Rx) and the downlink operating band of band B (B-Rx), and the cellular module 5 may support three or more communication bands.

In the sixth modified example, the radio-frequency circuit 1F having the same configuration as that of the radio-frequency circuit 1D of the fourth modified example is connected to the antennas 2C and 2D via the switch 56. However, the radio-frequency circuit to be connected to the antennas 2C and 2D via the switch 56 is not limited to the radio-frequency circuit 1F.

For example, any one of the radio-frequency circuit 1 of the embodiment, the radio-frequency circuit 1A of the first modified example, the radio-frequency circuit 1B of the second modified example, the radio-frequency circuit 1C of the third modified example, the radio-frequency circuit 1E of the fifth modified example may be connected to the antennas 2C and 2D via the switch 56 of the cellular module 5.

### 8 Advantages and Others

As described above, a radio-frequency circuit 1 according to the embodiment includes filters 10 and 20 and a switch 50. The filter 10 has a pass band including a first broadcast band for 5G broadcast. The filter 20 has a pass band including a second broadcast band for 5G broadcast and a first communication band for cellular mobile communication. The switch 50 includes terminals 50a, 50b, and 50c. The switch 50 switches between the connection of the terminal 50a to the terminal 50b and the disconnection of the terminal 50a from the terminal 50b and also switches between the connection of the terminal 50a to the terminal 50c and the disconnection of the terminal 50a from the terminal 50c. The second broadcast band and the first communication band at least partially overlap each other and are positioned at a high frequency side or a low frequency side of the first broadcast band. The filter 10 is connected to the terminal 50b. The filter 20 is connected to the terminal 50c.

With the above-described configuration, the 5G broadcast filter is constituted by the filter 10 having the pass band including the first broadcast band and the filter 20 having the pass band including the second broadcast band. This can secure a large frequency interval between the pass band of the filter 10 and the existing cellular communication band located close to the high frequency side or the low frequency side of the second broadcast band. The filter 10 can thus secure the attenuation of this existing cellular communication band. Regarding the filter 20 having the pass band including the second broadcast band, a filter having a pass band including the first communication band, which is an existing cellular communication band, can be used as the filter 20. The filter 20 does not increase the pass band width and can thus secure a sufficient attenuation of the existing cellular communication band close to the second broadcast band. Hence, the radio-frequency circuit 1 is able to receive a 5G broadcast signal while reducing interference with a cellular communication band. The filter 10 used for 5G broadcast does not need to increase the pass band width and can thus be reduced in size. The filter 20 can be used both for an existing cellular communication band and the second broadcast band. It is thus possible to provide a small radio-frequency circuit 1 that can receive a 5G broadcast signal and also perform cellular communication using the first communication band.

In one example, in the radio-frequency circuit 1, the filter 10 is an LC filter including an inductor and a capacitor, while the filter 20 is an acoustic wave filter including an acoustic wave resonator.

With this configuration, the filter 10 can be formed by a low-loss and small-sized LC filter, while the filter 20 can secure a large attenuation of the cellular communication band close to the second broadcast band.

In one example, in the radio-frequency circuit 1, the switch 50 mutually exclusively performs the connection of the terminal 50a to the terminal 50b and the connection of the terminal 50a to the terminal 50c.

This enables the radio-frequency circuit 1 to selectively perform the following operations: (1) receiving a 5G broadcast signal of the first broadcast band; and (2) receiving a 5G broadcast signal of the second broadcast band and/or performing communication of a cellular network signal of the first communication band.

In one example, in the radio-frequency circuit 1, the first communication band includes an uplink operating band.

This enables the radio-frequency circuit 1 to selectively perform the following operations: (1) receiving a 5G broadcast signal of the first broadcast band; (2) receiving a 5G broadcast signal of the second broadcast band; and (3) transmitting a cellular network signal of the first communication band.

In one example, in the radio-frequency circuit 1, the first broadcast band is 470 to 663 MHz; the second broadcast band is 663 to 702 MHz; and the first communication band is one of the uplink operating band of band 71 or band 105 for 4G-LTE and the uplink operating band of band n71 or band n105 for 5G-NR.

With this configuration, it is possible to provide a radio-frequency circuit 1 that can receive a 5G broadcast signal while reducing interference with a cellular communication band in the UHF (Ultra High Frequency) band.

In one example, the radio-frequency circuit 1 also includes a low-noise amplifier 30, a power amplifier 40, and a switch 60. The switch 60 includes terminals 60a, 60b, 60c, and 60d. The switch 60 switches between the connection of the terminal 60c to the terminal 60a and the connection of the 60c to the terminal 60b and switches between the connection of the terminal 60b to the terminal 60c and the connection of the terminal 60b to the terminal 60d. The terminal 60a is connected to the filter 10. The terminal 60b is connected to the filter 20. The terminal 60c is connected to the low-noise amplifier 30. The terminal 60d is connected to the power amplifier 40.

With this configuration, the radio-frequency circuit 1 is able to selectively execute the following operations: (1) amplifying a 5G broadcast reception signal of the first broadcast band; (2) amplifying a 5G broadcast reception signal of the second broadcast band; and (3) amplifying a cellular network signal of the first communication band.

A radio-frequency circuit 1D according to the fourth modified example includes filters 11 and 12 and a switch 54. The filter 11 has a pass band including the first broadcast band for 5G broadcast. The filter 12 has a pass band including the second broadcast band for 5G broadcast and the first communication band for cellular mobile communication. The switch 54 includes terminals 54a, 54b, and 54c. The switch 54 switches between the connection of the terminal 54a to the terminal 54b and the disconnection of the terminal 54a from the terminal 54b and also switches between the connection of the terminal 54a to the terminal 54c and the disconnection of the terminal 54a from the terminal 54c. The second broadcast band and the first communication band at least partially overlap each other and are positioned at a high frequency side or a low frequency side of the first broadcast band. The filter 11 is connected to the terminal 54b. The filter 12 is connected to the terminal 54c. The first communication band includes a downlink operating band.

With the above-described configuration, the 5G broadcast filter is constituted by the filter 11 having the pass band including the first broadcast band and the filter 12 having the pass band including the second broadcast band. This can secure a large frequency interval between the pass band of the filter 11 and the existing cellular communication band located close to the high frequency side of the second broadcast band. The filter 11 can thus secure the attenuation of this existing cellular communication band. Regarding the filter 12 having the pass band including the second broadcast band, a filter having a pass band including the first communication band, which is an existing cellular communication band, can be used as the filter 12. The filter 12 does not increase the pass band width and can thus secure a sufficient attenuation of the existing cellular communication band close to the second broadcast band. Hence, the radio-frequency circuit 1D is able to receive a 5G broadcast signal while reducing interference with a cellular communication band. The filter 11 used for 5G broadcast does not need to increase the pass band width and can thus be reduced in size. The filter 12 can be used both for an existing cellular communication band and the second broadcast band for 5G broadcast. It is thus possible to provide a small radio-frequency circuit 1D that can receive both of a 5G broadcast signal and a cellular network signal using the first communication band.

In one example, in the radio-frequency circuit 1D, the first broadcast band is 470 to 612 MHz; the second broadcast band is 612 to 652 MHz; and the first communication band is one of the downlink operating band of band 71 or band 105 for 4G-LTE and the downlink operating band of band n71 or band n105 for 5G-NR.

It is thus possible to provide a radio-frequency circuit 1D that can receive a 5G broadcast signal while reducing interference with a cellular communication band in the UHF band.

In one example, the radio-frequency circuit 1D also includes a low-noise amplifier 30 and a switch 63. The switch 63 includes terminals 63a, 63b, and 63c. The switch 63 switches between the connection of the terminal 63a to the terminal 63b and connection of the terminal 63a to the terminal 63c. The terminal 63b is connected to the filter 11. The terminal 63c is connected to the filter 12. The terminal 63a is connected to the low-noise amplifier 30.

With this configuration, the radio-frequency circuit 1D is able to selectively execute the following operations: (1) amplifying a 5G broadcast reception signal of the first broadcast band; (2) amplifying a 5G broadcast reception signal of the second broadcast band; and (3) amplifying a cellular network reception signal of the first communication band.

A radio-frequency circuit 1A according to the first modified example includes filters 11, 20, and 12, and a switch 51. The filter 11 has a pass band including the first broadcast band for 5G broadcast. The filter 20 has a pass band including the second broadcast band for 5G broadcast and the first communication band for cellular mobile communication. The filter 12 has a pass band including a third broadcast band for 5G broadcast and the second communication band for cellular mobile communication. The switch 51 includes terminals 51a, 51b, 51c, and 51d. The switch 51 switches between the connection of the terminal 51a to the terminal 51b and the disconnection of the terminal 51a from the terminal 51b, switches between the connection of the terminal 51a to the terminal 51c and the disconnection of the terminal 51a from the terminal 51c, and also switches between the connection of the terminal 51a to the terminal 51d and the disconnection of the terminal 51a from the terminal 51d. The second broadcast band and the first communication band at least partially overlap each other and are positioned at the high frequency side or the low frequency side of the first broadcast band. The third broadcast band and the second communication band at least partially overlap each other and are positioned between the first broadcast band and the second broadcast band. The filter 11 is connected to the terminal 51b. The filter 12 is connected to the terminal 51c. The filter 20 is connected to the terminal 51d.

With the above-described configuration, the 5G broadcast filter is constituted by the filter 11 having the pass band including the first broadcast band, the filter 12 having the pass band including the third broadcast band, and the filter 20 having the pass band including the second broadcast band. This can secure a large frequency interval between the pass band of the filter 11 and the existing cellular communication band located close to the high frequency side of the second broadcast band. The filter 11 can thus secure the attenuation of this existing cellular communication band. Regarding the filter 20 having the pass band including the second broadcast band, a filter having a pass band including the first communication band, which is an existing cellular communication band, can be used as the filter 20. The filter 20 does not increase the pass band width and can thus secure a sufficient attenuation of the existing cellular communication band close to the second broadcast band. Regarding the filter 12 having the pass band including the third broadcast band, a filter having a pass band including the second communication band, which is an existing cellular communication band, can be used as the filter 12. The filter 12 does not increase the pass band width and can thus secure a sufficient attenuation of the existing cellular communication band close to the second broadcast band. Hence, the radio-frequency circuit 1A is able to receive a 5G broadcast signal while reducing interference with a cellular communication band. The filter 11 used for 5G broadcast does not need to increase the pass band width and can thus be reduced in size. The filter 20 can be used both for an existing cellular communication band and the second broadcast band for 5G broadcast. The filter 12 can be used both for an existing cellular communication band and the third broadcast band for 5G broadcast. It is thus possible to provide a small radio-frequency circuit 1A that can be used both for receiving a 5G broadcast signal and performing cellular network communication using the first communication band and the second communication band.

In one example, in the radio-frequency circuit 1A, the switch 51 mutually exclusively performs the connection of the terminal 51a to the terminal 51b, the connection of the terminal 51a to the terminal 51c, and the connection of the terminal 51a to the terminal 51d.

This enables the radio-frequency circuit 1A to selectively perform the following operations: (1) receiving a 5G broadcast signal of the first broadcast band; (2) receiving a 5G broadcast signal of the second broadcast band and/or performing communication of a cellular network signal of the first communication band; and (3) receiving a 5G broadcast signal of the third broadcast band and/or performing communication of a cellular network signal of the second communication band.

In one example, in the radio-frequency circuit 1A, the first communication band includes the uplink operating band, and the second communication band includes the downlink operating band.

This enables the radio-frequency circuit 1A to selectively perform the following operations: (1) receiving a 5G broadcast signal of the first broadcast band; (2) receiving a 5G broadcast signal of the second broadcast band and/or transmitting a cellular network signal of the first communication band; and (3) receiving a 5G broadcast signal of the third broadcast band and/or receiving a cellular network signal of the second communication band.

In one example, in the radio-frequency circuit 1A, the first broadcast band is 470 to 612 MHz; the second broadcast band is 663 to 702 MHz; and the third broadcast band is 612 to 652 MHZ. The first communication band is one of the uplink operating band of band 71 or band 105 for 4G-LTE and the uplink operating band of band n71 or band n105 for 5G-NR. The second communication band is one of the downlink operating band of band 71 or band 105 for 4G-LTE and the downlink operating band of band n71 or band n105 for 5G-NR.

With this configuration, it is possible to provide a radio-frequency circuit 1A that can receive a 5G broadcast signal while reducing interference with a cellular communication band in the UHF band.

In one example, the radio-frequency circuit 1A also includes a low-noise amplifier 30, a power amplifier 40, and a switch 61. The switch 61 includes terminals 61a, 61b, 61c, 61d, and 61e. The switch 61 switches between the connection of the terminal 61d to the terminal 61a, the connection of the terminal 61d to the terminal 61b, and the connection of the terminal 61d to the terminal 61c and also switches between the connection of the terminal 61c to the terminal 61d and the connection of the terminal 61c to the terminal 61e. The terminal 61a is connected to the filter 11. The terminal 61c is connected to the filter 20. The terminal 61b is connected to the filter 12. The terminal 61d is connected to the low-noise amplifier 30. The terminal 61e is connected to the power amplifier 40.

With the above-described configuration, the radio-frequency circuit 1A is able to selectively execute the following operations: (1) amplifying a 5G broadcast reception signal of the first broadcast band; (2) amplifying a 5G broadcast reception signal of the second broadcast band; (3) amplifying a 5G broadcast reception signal of the third broadcast band; (4) amplifying a cellular network transmission signal of the first communication band; and (5) amplifying a cellular network reception signal of the second communication band.

In one example, the radio-frequency circuit 1A also includes radio-frequency output terminals 111 and 112 and a switch 71. The radio-frequency output terminal 111 is connected to an RFIC 3A that processes a 5G broadcast signal. The radio-frequency output terminal 112 is connected to an RFIC 3B that processes a cellular network signal. The switch 71 switches the connection of the output end of the low-noise amplifier 30 to the radio-frequency output terminal 111 and the connection of the output end of the low-noise amplifier 30 to the radio-frequency output terminal 112.

With this configuration, the radio-frequency circuit 1A is able to output a 5G broadcast reception signal amplified by the low-noise amplifier 30 to the RFIC 3A and to output a cellular network reception signal of the second communication band amplified by the low-noise amplifier 30 to the RFIC 3B.

In one example, a radio-frequency circuit 1B according to the second modified example includes filters 11, 20, and 12, a switch 51, low-noise amplifiers 31 and 32, a power amplifier 40, and a switch 62. The switch 62 includes terminals 62a, 62b, 62c, 62d, 62e, and 62f. The switch 62 switches between the connection of the terminal 62d to the terminal 62a, the connection of the terminal 62d to the terminal 62c, and the connection of the terminal 62d to the terminal 62b, switches between the connection of the terminal 62b to the terminal 62d and the connection of the terminal 62b to the terminal 62e, and switches between the connection of the terminal 62c to the terminal 62d and the connection of the terminal 62c to the terminal 62e. The terminal 62a is connected to the filter 11. The terminal 62c is connected to the filter 20. The terminal 62b is connected to the filter 12. The terminal 62d is connected to the low-noise amplifier 31. The terminal 62e is connected to the low-noise amplifier 32. The terminal 62f is connected to the power amplifier 40.

With the above-described configuration, in the radio-frequency circuit 1B, the low-noise amplifier 31 can be used as a dedicated amplifier for 5G broadcast, while the low-noise amplifier 32 can be used as a dedicated amplifier for cellular network communication. The radio-frequency circuit 1B is able to selectively execute the following operations: (1) amplifying a 5G broadcast reception signal of the first broadcast band; (2) amplifying a 5G broadcast reception signal of the second broadcast band; (3) amplifying a 5G broadcast reception signal of the third broadcast band; (4) amplifying a cellular network transmission signal of the first communication band; and (5) amplifying a cellular network reception signal of the downlink operating band of the second communication band.

In one example, the radio-frequency circuit 1B also includes radio-frequency output terminals 111 and 112. The radio-frequency output terminal 111 is connected to an RFIC 3A that processes a 5G broadcast signal. The radio-frequency output terminal 112 is connected to an RFIC 3B that processes a cellular network signal. The output end of the low-noise amplifier 31 is connected to the radio-frequency output terminal 111. The output end of the low-noise amplifier 32 is connected to the radio-frequency output terminal 112.

With this configuration, the radio-frequency circuit 1B is able to output a 5G broadcast reception signal amplified by the low-noise amplifier 31 to the RFIC 3A and to output a cellular network reception signal of the second communication band amplified by the low-noise amplifier 32 to the RFIC 3B.

In one example, a radio-frequency circuit 1E according to the fifth modified example includes filters 11, 20, 12, and 22 and a switch 55. The filter 22 has a pass band including a third communication band for cellular mobile communication. The switch 55 includes terminals 55a, 55b, 55c, 55d, 55e, and 55f. The terminal 55a is connected to an antenna 2A. The terminal 55b is connected to an antenna 2B. The terminal 55c is connected to the filter 11. The terminal 55d is connected to the filters 12 and 20. The terminal 55f is connected to the filter 22. The second broadcast band is positioned between the third communication band and the third broadcast band. When a 5G broadcast signal of the first broadcast band and a cellular network signal of the second communication band are to be simultaneously received, the terminals 55a and 55c are connected to each other and the terminals 55b and 55d are connected to each other. When a cellular network signal of the second communication band and a cellular network signal of the third communication band are to be simultaneously received, the terminals 55a and 55d are connected to each other and the terminals 55b and 55f are connected to each other.

With this configuration, the radio-frequency circuit 1E can selectively perform the following operations: (1) receiving a 5G broadcast signal of the first broadcast band; (2) receiving a 5G broadcast signal of the second broadcast band and/or transmitting a cellular network signal of the first communication band; (3) receiving a 5G broadcast signal of the third broadcast band and/or receiving a cellular network signal of the second communication band; and (4) receiving a cellular network signal of the third communication band. The radio-frequency circuit 1E can also perform the following operations: (5) simultaneously receiving a 5G broadcast signal of the first broadcast band and receiving a cellular network signal of the second communication band; and (6) simultaneously receiving a cellular network signal of the second communication band and a cellular network signal of the third communication band.

In one example, in the radio-frequency circuit 1E according to the fifth modified example, the first broadcast band is 470 to 612 MHz; the second broadcast band is 663 to 702 MHz; the third broadcast band is 612 to 652 MHZ; the first communication band is one of the uplink operating band of band 71 or band 105 for 4G-LTE and the uplink operating band of band n71 or band n105 for 5G-NR; the second communication band is one of the downlink operating band of band 71 or band 105 for 4G-LTE and the downlink operating band of band n71 or band n105 for 5G-NR; and the third communication band is one of the downlink operating band of band 28 for 4G-LTE and the downlink operating band of band n28 for 5G-NR.

With this configuration, it is possible to provide a radio-frequency circuit 1E that can receive a 5G broadcast signal while reducing interference with a cellular communication band in the UHF band.

In one example, in a radio-frequency circuit 1F according to the sixth modified example, the antenna connection terminal 100 is an external connection terminal connected to a switch 56 of a cellular module 5. The cellular module 5 is an independent component different from the radio-frequency circuit 1F. The cellular module 5 includes a filter 23 having a pass band including the first communication band. The antenna connection terminal 100 is connected to an antenna 2C or 2D via the switch 56.

With this configuration, the radio-frequency circuit 1F is able to receive a 5G broadcast signal by the antennas 2C and 2D used for cellular communication. It is thus possible to provide a small communication device 4F that can be used both for 5G broadcast reception and cellular communication using the first communication band.

### Other Embodiments

A radio-frequency circuit according to an embodiment of the present disclosure has been discussed above through illustration of the embodiment and modified examples, but it is not restricted to the above-described embodiment and modified examples. Other embodiments implemented by combining certain elements in the above-described embodiment and modified examples and other modified examples obtained by making various modifications to the above-described embodiment and modified examples by those skilled in the art without departing from the scope and spirit of the disclosure are also encompassed in the disclosure. Various types of equipment integrating any of the above-described radio-frequency circuits are also encompassed in the disclosure.

In one example, in the circuit configurations of the radio-frequency circuits according to the above-described embodiment and modified examples, another circuit element and another wiring may be inserted onto a path connecting circuit elements and/or onto a path connecting signal paths illustrated in the drawings.

In the above-described embodiment and modified examples, cellular bands for 5G-NR or LTE are used. In addition to or instead of 5G-NR or LTE, however, a communication band for another RAT may be used. For example, a communication band for a WLAN may be used.

The features of the radio-frequency circuits discussed through illustration of the above-described embodiment and modified examples are as follows.

<1>

A radio-frequency circuit comprising:
a first filter having a pass band including a first broadcast band for 5G broadcast;
a second filter having a pass band including a second broadcast band for 5G broadcast and a first communication band for cellular mobile communication; and
a first switch that includes first, second, and third terminals and that switches between connection of the first terminal to the second terminal and disconnection of the first terminal from the second terminal and also switches between connection of the first terminal to the third terminal and disconnection of the first terminal from the third terminal,
wherein the second broadcast band and the first communication band at least partially overlap each other and are positioned at a high frequency side or a low frequency side of the first broadcast band, and
wherein the first terminal is connected to an antenna connection terminal, the second terminal is connected to the first filter, and the third terminal is connected to the second filter.
   <2>

The radio-frequency circuit according to <1>, wherein:
the first filter is an LC filter including an inductor and a capacitor; and
the second filter is an acoustic wave filter including an acoustic wave resonator.
   <3>

The radio-frequency circuit according to <1> or <2>, wherein the first switch mutually exclusively performs the connection of the first terminal to the second terminal and the connection of the first terminal to the third terminal.

<4>

The radio-frequency circuit according to one of <1> to <3>, wherein the first communication band includes an uplink operating band.

<5>

The radio-frequency circuit according to <4>, wherein:
the first broadcast band is 470 to 663 MHZ;
the second broadcast band is 663 to 702 MHZ; and
the first communication band is one of the uplink operating band of band 71 or band 105 for 4G-LTE and the uplink operating band of band n71 or band n105 for 5G-NR.
   <6>

The radio-frequency circuit according to <4> or <5>, further comprising:
a first low-noise amplifier;
a first power amplifier; and
a second switch that includes fourth, fifth, sixth, and seventh terminals and that switches between connection of the sixth terminal to the fourth terminal and connection of the sixth terminal to the fifth terminal and switches between connection of the fifth terminal to the sixth terminal and connection of the fifth terminal to the seventh terminal, wherein
the fourth terminal is connected to the first filter,
the fifth terminal is connected to the second filter,
the sixth terminal is connected to the first low-noise amplifier, and
the seventh terminal is connected to the first power amplifier.
   <7>

The radio-frequency circuit according to one of <1> to <3>, wherein the first communication band includes a downlink operating band.

<8>

The radio-frequency circuit according to <7>, wherein:
the first broadcast band is 470 to 612 MHz;
the second broadcast band is 612 to 652 MHZ; and
the first communication band is one of the downlink operating band of band 71 or band 105 for 4G-LTE and the downlink operating band of band n71 or band n105 for 5G-NR.
   <9>

The radio-frequency circuit according to <7> or <8>, further comprising:
a first low-noise amplifier; and
a third switch that includes fourth, fifth, and sixth terminals and that switches between connection of the sixth terminal to the fourth terminal and connection of the sixth terminal to the fifth terminal, wherein
the fourth terminal is connected to the first filter,
the fifth terminal is connected to the second filter, and
the sixth terminal is connected to the first low-noise amplifier.
   <10>

The radio-frequency circuit according to one of <1> to <4>, further comprising:
a third filter having a pass band including a third broadcast band for 5G broadcast and a second communication band for cellular mobile communication, wherein
the first switch further includes an eighth terminal and switches between connection of the eighth terminal to the first terminal and disconnection of the eighth terminal from the first terminal,
the third broadcast band and the second communication band at least partially overlap each other and are positioned between the first broadcast band and the second broadcast band, and
the third filter is connected to the eighth terminal.
   <11>

The radio-frequency circuit according to <10>, wherein the first switch mutually exclusively performs the connection of the first terminal to the second terminal, the connection of the first terminal to the third terminal, and the connection of the first terminal to the eighth terminal.

<12>

The radio-frequency circuit according to <10> or <11>, wherein the second communication band includes a downlink operating band.

<13>

The radio-frequency circuit according to <12>, wherein:
the first broadcast band is 470 to 612 MHz;
the second broadcast band is 663 to 702 MHZ;
the third broadcast band is 612 to 652 MHZ;
the first communication band is one of an uplink operating band of band 71 or band 105 for 4G-LTE and an uplink operating band of band n71 or band n105 for 5G-NR; and
the second communication band is one of the downlink operating band of band 71 or band 105 for 4G-LTE and the downlink operating band of band n71 or band n105 for 5G-NR.
   <14>

The radio-frequency circuit according to <12> or <13>, further comprising:
a first low-noise amplifier;
a first power amplifier; and
a fourth switch that includes fourth, fifth, sixth, seventh, and ninth terminals and that switches between connection of the sixth terminal to the fourth terminal, connection of the sixth terminal to the fifth terminal, and the connection of the sixth terminal to the ninth terminal and switches between connection of the fifth terminal to the sixth terminal and connection of the fifth terminal to the seventh terminal, wherein
the fourth terminal is connected to the first filter,
the fifth terminal is connected to the second filter,
the ninth terminal is connected to the third filter,
the sixth terminal is connected to the first low-noise amplifier, and
the seventh terminal is connected to the first power amplifier.
   <15>

The radio-frequency circuit according to <14>, further comprising:
a first external connection terminal connected to a first signal processing circuit that processes a 5G broadcast signal;
a second external connection terminal connected to a second signal processing circuit that processes a cellular network signal; and
a fifth switch that switches connection of an output end of the first low-noise amplifier to the first external connection terminal and connection of the output end of the first low-noise amplifier to the second external connection terminal.
   <16>

The radio-frequency circuit according to <12> or <13>, further comprising:
a first low-noise amplifier;
a second low-noise amplifier;
a first power amplifier; and
a sixth switch that includes fourth, fifth, sixth, seventh, ninth, and tenth terminals and that switches between connection of the sixth terminal to the fourth terminal, connection of the sixth terminal to the fifth terminal, and the connection of the sixth terminal to the ninth terminal, switches between connection of the ninth terminal to the sixth terminal and connection of the ninth terminal to the tenth terminal, and switches between connection of the fifth terminal to the sixth terminal and connection of the fifth terminal to the seventh terminal, wherein
the fourth terminal is connected to the first filter,
the fifth terminal is connected to the second filter,
the ninth terminal is connected to the third filter,
the sixth terminal is connected to the first low-noise amplifier,
the tenth terminal is connected to the second low-noise amplifier, and
the seventh terminal is connected to the first power amplifier.
   <17>

The radio-frequency circuit according to <16>, further comprising:
a first external connection terminal connected to a first signal processing circuit that processes a 5G broadcast signal; and
a second external connection terminal connected to a second signal processing circuit that processes a cellular network signal,
wherein an output end of the first low-noise amplifier is connected to the first external connection terminal, and
wherein an output end of the second low-noise amplifier is connected to the second external connection terminal.
   <18>

The radio-frequency circuit according to one of <10> to <17>, further comprising:
a fourth filter having a pass band including a third communication band for cellular mobile communication, wherein
the first switch further includes eleventh and twelfth terminals, the first terminal is connected to a first antenna, the eleventh terminal is connected to a second antenna, and the twelfth terminal is connected to the fourth filter,
the second broadcast band is positioned between the third communication band and the third broadcast band,
when a 5G broadcast signal of the first broadcast band and a cellular network signal of the second communication band are to be simultaneously received, the first terminal and the second terminal are connected to each other and the eleventh terminal and the eighth terminal are connected to each other, and
when a cellular network signal of the second communication band and a cellular network signal of the third communication band are to be simultaneously received, the first terminal and the eighth terminal are connected to each other and the eleventh terminal and the twelfth terminal are connected to each other.
   <19>

The radio-frequency circuit according to <18>, wherein:
the first broadcast band is 470 to 612 MHz;
the second broadcast band is 663 to 702 MHZ;
the third broadcast band is 612 to 652 MHZ;
the first communication band is one of an uplink operating band of band 71 or band 105 for 4G-LTE and an uplink operating band of band n71 or band n105 for 5G-NR;
the second communication band is one of a downlink operating band of band 71 or band 105 for 4G-LTE and a downlink operating band of band n71 or band n105 for 5G-NR; and
the third communication band is one of a downlink operating band of band 28 for 4G-LTE and a downlink operating band of band n28 for 5G-NR.
   <20>

The radio-frequency circuit according to one of <1> to <19>, wherein:
the antenna connection terminal is an external connection terminal connected to a seventh switch of a cellular module, the cellular module being a component different from the radio-frequency circuit;
the cellular module includes a fifth filter having a pass band including the first communication band; and
the antenna connection terminal is connected to an antenna via the seventh switch.

The present invention can be widely used for communication equipment, such as a mobile phone, as a radio-frequency circuit disposed in a front-end section.

What is claimed is:

1. A radio-frequency circuit comprising:
a first filter having a pass band including a first broadcast band for 5G broadcast;
a second filter having a pass band including a second broadcast band for 5G broadcast and a first communication band for cellular mobile communication; and
a first switch including a first terminal connected to an antenna connection terminal, a second terminal connected to the first filter, and a third terminal connected to the second filter, wherein
the first switch is configured to connect the first terminal to at least one of the second terminal and the third terminal, and
the second broadcast band and the first communication band at least partially overlap each other and are positioned at a high frequency side or a low frequency side of the first broadcast band.

2. The radio-frequency circuit according to claim 1, wherein:
the first filter is an LC filter including an inductor and a capacitor; and
the second filter is an acoustic wave filter including an acoustic wave resonator.

3. The radio-frequency circuit according to claim 1, wherein the first switch mutually exclusively connect the first terminal to the second terminal and connect the first terminal to the third terminal.

4. The radio-frequency circuit according to claim 1, wherein the first communication band includes an uplink operating band.

5. The radio-frequency circuit according to claim 4, wherein:
the first broadcast band is 470 to 663 MHZ;
the second broadcast band is 663 to 702 MHz; and
the first communication band is one of the uplink operating band of band 71 or band 105 for 4G-LTE and the uplink operating band of band n71 or band n105 for 5G-NR.

6. The radio-frequency circuit according to claim 4, further comprising:
a first low-noise amplifier;
a first power amplifier; and
a second switch including fourth, fifth, sixth, and seventh terminals, wherein the second switch is configured to selectively connect the sixth terminal to one of the fourth terminal and the fifth terminal and the second switch is further configured to selectively connect the fifth terminal to one of the sixth terminal and the seventh terminal, wherein
the fourth terminal is connected to the first filter,
the fifth terminal is connected to the second filter,
the sixth terminal is connected to the first low-noise amplifier, and
the seventh terminal is connected to the first power amplifier.

7. The radio-frequency circuit according to claim 1, wherein the first communication band includes a downlink operating band.

8. The radio-frequency circuit according to claim 7, wherein:
the first broadcast band is 470 to 612 MHz;
the second broadcast band is 612 to 652 MHZ; and
the first communication band is one of the downlink operating band of band 71 or band 105 for 4G-LTE and the downlink operating band of band n71 or band n105 for 5G-NR.

9. The radio-frequency circuit according to claim 7, further comprising:
a first low-noise amplifier; and
a third switch including fourth, fifth, and sixth terminals, wherein the third switch is configured to selectively connect the sixth terminal to one of the fourth terminal and the fifth terminal, wherein
the fourth terminal is connected to the first filter,
the fifth terminal is connected to the second filter, and
the sixth terminal is connected to the first low-noise amplifier.

10. The radio-frequency circuit according to claim 1, further comprising:
a third filter having a pass band including a third broadcast band for 5G broadcast and a second communication band for cellular mobile communication, wherein
the first switch further includes an eighth terminal and switches between connection of the eighth terminal to the first terminal and disconnection of the eighth terminal from the first terminal,
the third broadcast band and the second communication band at least partially overlap each other and are positioned between the first broadcast band and the second broadcast band, and
the third filter is connected to the eighth terminal.

11. The radio-frequency circuit according to claim 10, wherein the first switch mutually exclusively connects the first terminal to the second terminal, the first terminal to the third terminal, and the first terminal to the eighth terminal.

12. The radio-frequency circuit according to claim 10, wherein the second communication band includes a downlink operating band.

13. The radio-frequency circuit according to claim 12, wherein:
the first broadcast band is 470 to 612 MHz;
the second broadcast band is 663 to 702 MHZ;
the third broadcast band is 612 to 652 MHZ;
the first communication band is one of an uplink operating band of band 71 or band 105 for 4G-LTE and an uplink operating band of band n71 or band n105 for 5G-NR; and
the second communication band is one of the downlink operating band of band 71 or band 105 for 4G-LTE and the downlink operating band of band n71 or band n105 for 5G-NR.

14. The radio-frequency circuit according to claim 12, further comprising:
a first low-noise amplifier;
a first power amplifier; and
a fourth switch including fourth, fifth, sixth, seventh, and ninth terminals, wherein the fourth switch is configured to selectively connect the sixth terminal to one of the fourth terminal, the fifth terminal, and the ninth terminal, and if further configured to selectively connect the fifth terminal to one of the sixth terminal and the seventh terminal, wherein
the fourth terminal is connected to the first filter,
the fifth terminal is connected to the second filter,
the ninth terminal is connected to the third filter,
the sixth terminal is connected to the first low-noise amplifier, and
the seventh terminal is connected to the first power amplifier.

15. The radio-frequency circuit according to claim 14, further comprising:
a first external connection terminal connected to a first signal processing circuit that processes a 5G broadcast signal;
a second external connection terminal connected to a second signal processing circuit that processes a cellular network signal; and
a fifth switch configured to selectively connect an output end of the first low-noise amplifier to one of the first external connection terminal and the second external connection terminal.

16. The radio-frequency circuit according to claim 12, further comprising:
a first low-noise amplifier;
a second low-noise amplifier;
a first power amplifier; and
a sixth switch including fourth, fifth, sixth, seventh, ninth, and tenth terminals, wherein the sixth switch is configured to perform the following connections:
selectively connect the sixth terminal to one of the fourth terminal, the fifth terminal, and the ninth terminal,
selectively connect the ninth terminal to one of the sixth terminal and the tenth terminal, and
selectively connect the fifth terminal to one of the sixth terminal and the seventh terminal, wherein
the fourth terminal is connected to the first filter,
the fifth terminal is connected to the second filter,
the ninth terminal is connected to the third filter,
the sixth terminal is connected to the first low-noise amplifier,
the tenth terminal is connected to the second low-noise amplifier, and
the seventh terminal is connected to the first power amplifier.

17. The radio-frequency circuit according to claim 16, further comprising:
a first external connection terminal connected to a first signal processing circuit that processes a 5G broadcast signal; and
a second external connection terminal connected to a second signal processing circuit that processes a cellular network signal,
wherein an output end of the first low-noise amplifier is connected to the first external connection terminal, and
wherein an output end of the second low-noise amplifier is connected to the second external connection terminal.

18. The radio-frequency circuit according to claim 10, further comprising:
a fourth filter having a pass band including a third communication band for cellular mobile communication, wherein
the first switch further includes eleventh and twelfth terminals, the first terminal is connected to a first antenna, the eleventh terminal is connected to a second antenna, and the twelfth terminal is connected to the fourth filter,
the second broadcast band is positioned between the third communication band and the third broadcast band,
when a 5G broadcast signal of the first broadcast band and a cellular network signal of the second communication band are to be simultaneously received, the first terminal and the second terminal are connected to each other and the eleventh terminal and the eighth terminal are connected to each other, and
when a cellular network signal of the second communication band and a cellular network signal of the third communication band are to be simultaneously received, the first terminal and the eighth terminal are connected to each other and the eleventh terminal and the twelfth terminal are connected to each other.

19. The radio-frequency circuit according to claim 18, wherein:
the first broadcast band is 470 to 612 MHz;
the second broadcast band is 663 to 702 MHZ;
the third broadcast band is 612 to 652 MHz;
the first communication band is one of an uplink operating band of band 71 or band 105 for 4G-LTE and an uplink operating band of band n71 or band n105 for 5G-NR;
the second communication band is one of a downlink operating band of band 71 or band 105 for 4G-LTE and a downlink operating band of band n71 or band n105 for 5G-NR; and
the third communication band is one of a downlink operating band of band 28 for 4G-LTE and a downlink operating band of band n28 for 5G-NR.

20. The radio-frequency circuit according to claim 1, wherein:
the antenna connection terminal is an external connection terminal connected to a seventh switch of a cellular module, the cellular module being a component different from the radio-frequency circuit;
the cellular module includes a fifth filter having a pass band including the first communication band; and
the antenna connection terminal is connected to an antenna via the seventh switch.
